(19) United States
(12) Patent Application Publication
(10) Pub. No.: US 2025/0344411 A1
(43) Pub. Date: Nov. 6, 2025

(54) LOGIC AND CACHE HYBRID BONDING

(71) Applicant: International Business Machines Corporation, Armonk, NY (US)

(72) Inventors: Ruilong Xie, Niskayuna, NY (US); Joshua M. Rubin, Albany, NY (US); Qianwen Chen, Chappaqua, NY (US); Cheng Chi, Jersey City, NJ (US); Tao Li, Slingerlands, NY (US)

(21) Appl. No.: 18/655,275

(22) Filed: May 5, 2024

(51) Int. Cl. H10B 80/00; H01L 21/683; H01L 23/00; H01L 25/18

(52) U.S. Cl. CPC H10B 80/00; H01L 21/6835; H01L 24/05; H01L 24/08; H01L 24/80; H01L 25/18; H01L 24/06; H01L 24/16; H01L 24/32; H01L 24/73; H01L 2221/6835; H01L 2224/05548; H01L 2224/06181; H01L 2224/08145; H01L 2224/16225; H01L 2224/32225; H01L 2224/73204; H01L 2224/80006; H01L 2224/80357; H01L 2224/80896; H01L 2924/1431; H01L 2924/1437

(57) ABSTRACT

A memory device comprises a physically and electrically connected logic die and a memory die. The logic die comprises a logic dielectric layer, with a plurality of logic openings; a logic device layer is disposed on the logic dielectric layer; and a plurality of logic devices, with logic device connections, disposed on/within the logic dielectric layer. The memory die comprises a memory dielectric layer with a plurality of memory openings; a memory device layer is disposed on the memory dielectric layer; and a plurality of memory devices, with memory device connections, disposed on/within the memory device layer. A backside to backside (B2B) connection interface is disposed between the logic dielectric layer and the memory dielectric layer. Connection paths passing through the B2B connection interface enables short back-to-back connections between logic device connections and the memory device connections.

### BACKGROUND

The present invention relates generally to the electrical, electronic and computer arts and, more particularly, to semiconductor structures and techniques of fabricating those semiconductor structures.

Combining both CMOS logic and SRAM memory hardware components and functions on a single die, chip, or wafer is difficult for conventional manufacturing processes because process flows for the logic functions/components are different and often incompatible with the process flows for the memory functions/components.

Accordingly, the industry trends involve fabricating the logic functions/components on one die, e.g. a logic die, with one process; fabricating the memory function (e.g. a static memory) on a separate die, e.g. a memory die, with other processes; and then to combining/connecting the logic die and memory die at frontside connections to form the completed memory chip (e.g., SRAM). As such, these traditional separate processes produce logic dies separately from memory dies and result in the logic and memory dies needing to be electrically connected through their front sides later in the process using a large plurality of connections.

However, as the complexity of these logic dies and memory dies increases, combining and connecting the logic and memory dies into a single chip becomes more challenging.

General prior art manufacturing processes make logic dies with multiple logic die backside layers, including one or more logic device layers, which include semiconductor logic devices and associated logic device connections. The logic dies have multiple frontside layers that are in the logic die opposite and across the logic die from the logic die backside layers.

Typically, the logic die frontside layer portion includes one or more logic die higher level frontside layers and one or more logic die lower-level frontside layers. Some of the higher level frontside layers have connections that form external electrical connections which connect externally to the logic die. These external electrical connections can include connections for power, signals, information, data and/or control. The logic die higher level frontside layers also have logic die higher level interconnects between the external electrical connections and the logic die lower level frontside layers within the logic die.

The logic die lower level frontside layers are between the higher level frontside layers and the logic die backside layers. The logic die backside layers contain the logic device layers where there are logic devices with logic device connections. The logic die lower level frontside layers have logic die lower level frontside layer interconnections that connect the logic device connections of the logic devices in the logic die backside layers to some of the logic die higher level interconnections and/or the external connections in the logic die frontside layers.

The logic die higher level frontside layers and the logic die lower level frontside layers generally have horizontal connections/wiring that stay within a particular horizontal layer. These logic die higher and lower frontside horizontal layers also contain logic die vias, or vertical connections, which pass through the one or more of the logic die horizontal layers. The logic die frontside horizontal layers are called logic die frontside metallization layers. In some prior art embodiments, there are passive components, e.g., resistors and capacitors, within these frontside metallization layers.

Accordingly, in the prior art, connections (power, signal, information, data and/or control connections) between the logic die connections (at the logic die backside) and the logic die external connections (at the logic die higher level frontside layers) must pass either directly and/or indirectly through all the logic die frontside (metallization) layers.

The prior art memory dies have a similar architecture, which specifically includes a plurality of memory die backside layers further including one or more memory die memory device layers (instead of a logic die device layer); one or more memory die lower level frontside layers; and one or more memory die higher-level frontside layers. These metallization layers in the memory dies can also include passive components.

On and/or within the memory die memory device layer(s) in the memory die backside there are a plurality of memory devices, e.g., memory cells, each with one or more memory device connections.

The memory die higher level frontside layers have one or more memory die external connections that connect to memory die.

The memory die lower level frontside layers are between the memory die higher level frontside layers and the memory die backside layers.

Accordingly, connections (power, signal, information, data and/or control connections) between the memory die external connections (at the memory die higher level frontside layers) and the memory device connections (at the memory die backside) must pass either directly and/or indirectly through all the memory die higher level frontside (metallization) layers, memory die lower level frontside layers, and memory die backside layers.

When integrating a logic die and memory die to make a memory chip/device, e.g., an SRAM, connections are made between the logic device connections and memory device/cell connections through the logic die frontside and memory die frontside. These connections are very long because the connections have to pass through a large number of metallization layers in both the logic and memory dies.

For example, these logic frontside to memory frontside connections connect from the logic device connections through the logic device backside layers, the logic die lower level frontside layers, the logic die higher level frontside layers, and the logic die external interconnections and then through the memory die external interconnections, through the memory die higher level frontside layers, the memory die lower level frontside layers, and the memory die backside layers, and ultimately to the memory device/cell connections in the memory die backside.

These logic die and memory die architectures are known.

The connections between the logic frontside and memory frontside result in longer, more dense, and more complicated internal logic die and memory die wiring. The large plurality of long connections connecting the logic and memory dies/devices can reduce the final chip (SRAM chip/device) performance and/or cause chip/device circuitry malfunctions.

These long connection distances cause interconnection delays that make memory chips/devices, e.g. SRAMs, fail to meet required communication speeds between the device/SRAM memory and logic circuitry.

While the long connection distances between logic device connections and memory device connections are less problematic in Dynamic Random Access Memory (DRAM) and Magnetoresistive Random Access Memory (MRAM), problems still may be caused by longer connection distances between the memory and logic device layers in these and other memory device/chip architectures as well.

Also, prior art frontside connections between logic device connections and memory device connections result in a large number of long through silicon vias (TSVs) that pass through the metallization layers of both the logic die and memory die. The larger number of TSVs is an additional cause of more dense and complicated circuitry/connections in the final memory chip.

### BRIEF SUMMARY

The structural embodiments of the present invention comprise a memory device (e.g., a memory chip) comprising a logic die and a memory die, physically bound together, and electrically connected to one another. Methods of making the memory device are disclosed.

The logic die comprises a logic dielectric layer, e.g., a logic electrically isolating layer, like a logic shallow trench isolation (STI) layer, which has a plurality of logic dielectric layer openings and a logic dielectric layer thickness. One or more logic device layers are disposed on the logic dielectric layer. The logic device layers have a logic device layer thickness. A plurality of logic devices are disposed on/within the logic device layers. Each of the logic devices has one or more logic device connections. The logic dielectric layer and the logic device layers are on a backside of the logic die.

The memory die comprises a memory dielectric layer, e.g. a memory electrically isolating layer like a memory STI, that has a plurality of memory dielectric layer openings and a memory dielectric layer thickness. One or more memory device layers are disposed on the memory dielectric layer and the memory device layers have a memory device layer thickness. A plurality of memory components/cells are disposed on/within the memory device layers. Each of the memory components/cells has one or more memory device/cell connections. The memory dielectric layer and the memory device layer are on a backside of the memory die.

A backside to backside (B2B) connection interface (B2B interface) has an interface memory side/surface and an interface logic side/surface. The interface memory side and interface logic side are opposite from one another across the B2B interface. The B2B interface has a B2B interface thickness. The B2B interface is disposed between the logic dielectric layer and the memory dielectric layer so that a backside of the memory dielectric/STI layer is disposed on the interface memory side and a backside of the logic dielectric/STI layer is disposed on the interface logic side.

The invention further comprises a plurality of connection paths. Each connection path electrically connects one or more of the logic device connections to one or more of the memory device/cell connections. The connection paths pass through the B2B interface enabling shorter connections (e.g., back-to-back connections) between the logic die (e.g., logic device connections) and the memory die (e.g., the memory device/cell connections).

In some embodiments, the connection paths are made of a conductive material and further comprise backside contacts. In some embodiments, the backside contacts comprise both logic backside contacts and memory backside contacts. Optionally, some connection paths further comprise one or more dielectric backside caps/contacts that modify the electrical characteristics of the respective connection path.

In some embodiments, the logic and/or memory backside contacts have cross-sections that are non-uniform, e.g. are tapered, so that one part of the cross-section of the logic and/or memory backside contact is smaller than a larger cross-section of other parts of the respective backside contact.

In some embodiments, the smaller cross-section of the logic (memory) backside contact passes through one of the logic (memory) dielectric openings in the logic (memory) STI to make the electrically connection with one or more of the logic (memory) device connections of the associated logic devices (memory cells).

In some embodiments, the larger cross-section region of the logic and/or memory backside contacts are within the B2B interface. In some embodiments, these larger cross-section regions of the logic backside contacts and associated memory backside contacts are bound together, e.g., by hybrid bonding, to form a backside redistribution layer/conductor (RDL) within the B2B interface.

In some embodiments, the optional dielectric caps are between the backside contacts and the backside RDL on the respective logic and/or memory sides within the B2B interface. Again, different dielectric cap materials are selected for these dielectric caps in order to individually modify the electrical characteristics of a particular connection path.

In some embodiments, each of the connection paths will have a length less than 600 nm and alternative less than 1200 nm.

### BRIEF DESCRIPTION OF THE DRAWINGS

Various embodiments of the present invention will be described below in more detail, by way of example and without limitation, with reference to the accompanying drawings, now briefly described. The Figures show various apparatus, structures, and related method steps of the present invention.

It is to be appreciated that elements in the figures are illustrated for simplicity and clarity. Common but well-understood elements that may be useful or necessary in a commercially feasible embodiment may not be shown to facilitate a less hindered view of the illustrated embodiments.

Refer to the Figures.

FIG. 1 is a cross-sectional view of an embodiment of a memory chip, e.g. a Static Random Access Memory (SRAM), with logic and memory functions combined on one chip/wafer and with short connection paths/connections between one or more logic device connections in a logic die and one or more memory device/cell connections in a memory die enabled by a backside to backside (B2B) connection interface between the logic die and the memory die.

FIG. 2 is a cross-sectional view of an embodiment of a B2B connection interface with partial circuitry of the logic die and memory die shown, i.e., some of the logic die and memory die circuitry is removed for clarity.

FIG. 3 is a cross-sectional view of an embodiment of an interim logic structure disposed on interim substrates showing a logic die with both logic local and logic global vias/wiring connected through connection openings in a logic dielectric layer, e.g., a logic shallow trench isolation (STI) layer.

FIG. 4 is a cross-sectional view of an embodiment of an interim structure of a logic die disposed on interim logic substrates, as shown in FIG. 3, with an interim logic device handler/carrier attached.

FIG. 5 is a cross-sectional view of an embodiment of the interim structure of the logic die disposed on the interim substrates of FIG. 4 but with one of the interim substrates removed.

FIG. 6 is a cross-sectional view of an embodiment of the interim structure of the logic die of FIG. 5 with a stop layer and/or the remainder of the other interim substrates removed and with the connection openings through the logic STI layer (the logic dielectric layer) exposed.

FIG. 7 is a cross-sectional view of an embodiment of an interim structure of a logic die (as shown in FIG. 6) with a partially formed logic interlayer dielectric (ILD), where the ILD dielectric fills one or more connection openings in the logic STI layer.

FIG. 8 is a cross-sectional view of an embodiment of the interim logic die structure shown in FIG. 7 with (tapered) logic backside contacts formed in a logic ILD and where each of the (smaller cross-section parts of the) logic backside contacts connects to one or more logic backside interconnects and directly contacts and/or passes through one of the logic connection openings of the logic STI layer and, further comprising, within the logic ILD, optional logic dielectric caps that are disposed on a larger cross-section part of one or more of the backside contacts.

FIG. 9 is a cross-sectional view of an embodiment of a logic die with a logic part of a B2B connection interface (logic interface) containing a completed logic interlayer dielectric (logic ILD) and one or more logic redistribution layer (logic RDLs) conductors (within the logic ILD), where each of the logic RDL conductors connects to a larger cross-section part of one or more of the logic backside contacts, respectively, and where each of the logic backside contacts has a smaller cross-section part that passes through one of the logic connection openings in the logic STI to connect with one or more logic backside interconnects forming a partial (logic) connection path, and where also some logic connection paths comprise an optional (logic) dielectric cap.

FIG. 10 is a cross-sectional view of an embodiment of an interim structure of a memory die with both memory local and memory global memory wiring connected through memory connection openings in a memory shallow trench isolation (STI) layer (a memory dielectric layer) and including interim memory substrates.

FIG. 11 is a cross-sectional view of an embodiment of an interim structure of memory die with some interim memory substrates attached, an interim memory device handler/carrier attached, and one of the interim substrates (shown in FIG. 10) removed.

FIG. 12 is a cross-sectional view of an embodiment of the interim structure of the memory die showing the remaining interim memory substrate(s) of FIG. 11 removed and showing the memory connection openings in the memory STI (the memory dielectric layer).

FIG. 13 is a cross-sectional view diagram of an embodiment of an interim structure of a memory die (shown in FIG. 12) with a memory part of a B2B connection interface (memory interface) containing a memory interlayer dielectric (memory ILD) and one or more memory redistribution layer (memory RDLs) conductors (within the memory ILD), where each of the memory RDL conductors connects to a larger cross-section part of one or more of the memory backside contacts, respectively, and where each of the memory backside contacts has a smaller cross-section part that passes through one of the memory connection openings in the memory STI to connect with one or more memory backside interconnects thus forming a partial (memory) connection path, and where some memory connection paths comprise an optional (memory) dielectric cap.

FIG. 14 is a cross-sectional view of an embodiment of a memory device, e.g., a SRAM device structure, that is a combination of a logic die and a memory die, where the logic and memory are connected back-to-back (B2B) through a B2B connection interface and also showing the electrical connection and bonding (e.g., hybrid bonding) between the logic RDL and memory RDL to form the final RDL conductors and complete the connection paths passing through the B2B connection interface.

FIG. 15 is sheet 1 of 2 sheets of a flow chart of a process for making a memory chip, e.g., a SRAM, which is a combination of a logic die and memory die where the logic and memory connections are connected by connection paths through a B2B connection interface.

FIG. 16 is sheet 2 of 2 sheets of a flow chart of a process for making a memory chip, e.g., a SRAM, which is a combination of a logic die and memory die where the logic and memory are connected B2B by connection paths through a B2B connection interface.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred. It is to be understood that embodiments of the present invention are not limited to the illustrative methods, apparatus, structures, systems and devices disclosed herein but instead are more broadly applicable to other alternative and broader methods, apparatus, structures, systems and devices that become evident to those skilled in the art given this disclosure.

In addition, it is to be understood that the various layers, structures, and/or regions shown in the accompanying drawings are not drawn to scale, and that one or more layers, structures, and/or regions of a type commonly used may not be explicitly shown in a given drawing. This does not imply that the layers, structures, and/or regions not explicitly shown are omitted from the actual devices.

In addition, certain elements may be left out of a view for the sake of clarity and/or simplicity when explanations are not necessarily focused on such omitted elements. Moreover, the same or similar reference numbers used throughout the drawings are used to denote the same or similar features, elements, or structures, and thus, a detailed explanation of the same or similar features, elements, or structures may not be repeated for each of the drawings.

The semiconductor devices, structures, and methods disclosed in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, expert and artificial intelligence systems, functional circuitry, neural networks, etc. Systems and hardware incorporating the semiconductor devices and structures are contemplated embodiments of the invention.

The terminology used herein is for the purpose of describing particular embodiments only and is not intended to be limiting.

As used herein, the singular forms “a,” “an” and “the” are intended to include the plural forms as well, unless the context clearly indicates otherwise.

It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

It should also be noted that, in some alternative implementations, some of the steps of the exemplary methods may occur out of the order noted in the figures. For example, two steps shown in succession may, in fact, be executed substantially concurrently, or certain steps may sometimes be executed in a different order, depending upon the functionality involved.

As used herein, “height” refers to a vertical size of an element (e.g., a layer, trench, hole, opening, etc.) in the cross-sectional or elevation views measured from a bottom surface to a top surface of the element, and/or measured with respect to a surface on which the element is located.

Conversely, a “depth” refers to a vertical size of an element (e.g., a layer, trench, hole, opening, etc.) in the cross-sectional or elevation views measured from a top surface to a bottom surface of the element. Terms such as “thick”, “thickness”, “thin” or derivatives thereof may be used in place of “height” or “depth” where indicated.

As used herein, “lateral,” “lateral side,” “side,” and “lateral surface” refer to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, terms such as “upper”, “lower”, “right”, “left”, “vertical”, “horizontal”, “top”, “bottom”, and derivatives thereof shall relate to the disclosed structures and methods, as oriented in the drawing figures. For example, as used herein, “vertical” refers to a direction perpendicular to the top surface of the substrate in the elevation views, and “horizontal” refers to a direction parallel to the top surface of the substrate in the elevation views.

As used herein, unless otherwise specified, terms such as “on”, “overlying”, “atop”, “on top”, “positioned on” or “positioned atop” mean that a first element is present on a second element, wherein intervening elements may be present between the first element and the second element.

As used herein, unless otherwise specified, the term “directly” used in connection with the terms “on”, “overlying”, “atop”, “on top”, “positioned on” or “positioned atop,” “disposed on,” or the terms “in contact” or “direct contact” means that a first element and a second element are connected without any intervening elements, such as, for example, intermediary conducting, insulating or semiconductor layers, present between the first element and the second element.

Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers.

It is understood that these terms might be affected by the orientation of the device described. For example, while the meaning of these descriptions might change if the device was rotated upside down, the descriptions remain valid because they describe relative relationships between features of the invention.

As the term is used herein and in the appended claims, “about” means within plus or minus ten percent, unless otherwise defined in this Specification.

Embodiments are referred to herein, individually and/or collectively, by the term “embodiment” merely for convenience and without intending to limit the scope of this Application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The corresponding structures, materials, acts, and equivalents of any means or step-plus-function elements in the claims below are intended to include any structure, material, or act for performing the function in combination with other claimed elements as specifically claimed.

The present invention has the advantages of improving connections between a logic die (e.g., a CMOS logic die) and a memory die (e.g., a SRAM memory die) that are integrated in a single semiconductor device, chip, or wafer to enable faster and more reliable memory devices/chips and to provide shorter and faster connections between logic and memory circuitry/functions within these memory devices/chips. Internal device/chip circuitry is also simplified. The invention has the advantages of improved manufacturing methods to integrate, e.g., CMOS logic and SRAM memory on a single device/chip/wafter with process flows that are compatible with both logic and memory functions and circuitry. Methods of making the memory devices/chips are disclosed.

The structural embodiments of the present invention, a memory device (e.g., a memory chip), comprise a logic die and a memory die physically bound together and electrically connected to one another through a backside to backside (back-to-back or B2B) connection interface (B2B interface).

The logic die comprises a logic dielectric layer, e.g. a logic electrically isolating layer or logic shallow trench isolation (STI) layer, which has a plurality of logic dielectric layer openings and a logic dielectric layer thickness. A logic device layer(s) is disposed on the logic dielectric layer. The logic device layer has a logic device layer thickness. A plurality of logic devices are disposed on/within the logic device layer. Each of the logic devices has one or more logic device connections.

The memory die comprises a memory dielectric layer, e.g. a memory electrically isolating layer or memory (STI), that has a plurality of memory dielectric layer openings and a memory dielectric layer thickness. A memory device layer(s) is disposed on the memory dielectric layer and the memory device layer has a memory device layer thickness. A plurality of memory devices/cells are disposed on/within the memory device layer. Each of the memory devices/cells has one or more memory device connections.

A backside to backside (B2B) connection interface (B2B interface) has an interface logic side/surface and an interface memory side/surface. The interface logic side and interface memory side are opposite from one another across the B2B interface. The B2B interface has a B2B interface thickness and the B2B interface is disposed between the logic dielectric layer and the memory dielectric layer so that the memory dielectric layer is disposed on the interface memory side and the logic dielectric layer is disposed on the interface logic side.

The invention further comprises a plurality of connection paths. Each connection path electrically connects one or more of the logic device connections to one or more of the memory device/cell connections. The connection paths pass through the B2B interface enabling shorter connections (e.g., back-to-back connections or B2B connections) between the logic die (e.g., logic device connections) and the memory die (e.g., the memory device/cell connections).

In some embodiments, the connection paths are made entirely of a conductive material (e.g., a metal like copper) and include backside logic contacts and backside memory contacts. In some embodiments the backside logic and/or backside memory contacts have a tapered shape (a taper). The tapered shape has a non-uniform cross-section, i.e., a part/end of the backside (logic and/or memory) contact cross-section is larger/broader and another part/end of the backside (logic and/or memory) contact cross-section is smaller/narrower. Example, tapered shapes include conical and pyramidal shapes, although other tapered shapes are contemplated.

In some embodiments, the smaller cross-section of the backside contacts fits through and/or is in proximity/contact with one of the (logic or memory, respectively) dielectric layer openings. In some embodiments, the larger cross-section of the backside (logic or memory, respectively) contact is contained within the B2B interface.

In some embodiments, the larger cross-section of one or more of the backside logic contacts is electrically connected to and/or forms a logic part of a redistribution layer (RDL), e.g. a logic RDL. Also, the larger cross-section of one or more of the backside memory contacts is electrically connected to and/or forms a memory part of an RDL, e.g., a memory RDL. Respective logic RDLs and memory RDLs are bound together and electrically connected, e.g., by hybrid bonding, to form a backside redistribution layer and/or conductor (RDLs) within the B2B interface. Bonding (e.g., hybrid bonding) one of the logic RDLs and one of the memory RDLs to form the (final) RDL/conductor completes one of the connection paths passing through the B2B connection interface.

In some embodiments, there is an optional logic dielectric cap connected within one or more of the connection paths. In some embodiments, the logic dielectric cap is between the larger cross-section of the logic backside contact and the respective logic RDL. The logic dielectric cap can be made of any of different dielectric materials to achieve a desired electrical characteristic of the respective connection path in which the logic dielectric cap is placed. Example logic dielectric cap materials include SiN, SiOCN, SiBCN, SiCO, SiC, SiCN, AlOx, AlNx, etc. Other dielectric materials are contemplated for making the logic (and memory, below) dielectric caps.

In some embodiments, there is an optional memory dielectric cap connected between a larger cross-section of one or more of the backside memory contacts and the respective memory RDL. As recited above, the memory dielectric cap can be made of any of different dielectric materials (as listed above for the logic dielectric caps) to achieve desired electrical characteristics of the respective connection path in which the memory dielectric cap is placed.

The connection paths are short, i.e., no longer than the aggregate thickness of the logic device layer thickness, the logic dielectric layer thickness, the B2B interface thickness, the memory dielectric layer thickness, and the memory device/cell layer thickness. In some embodiments, the connection path will be less than 600 nm and alternatively less than 1200 nm.

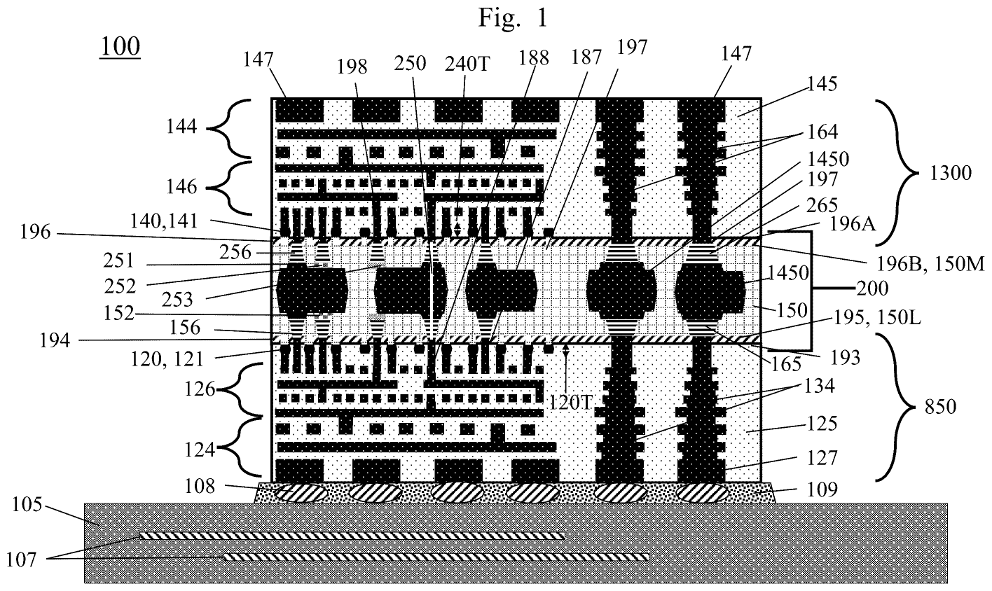

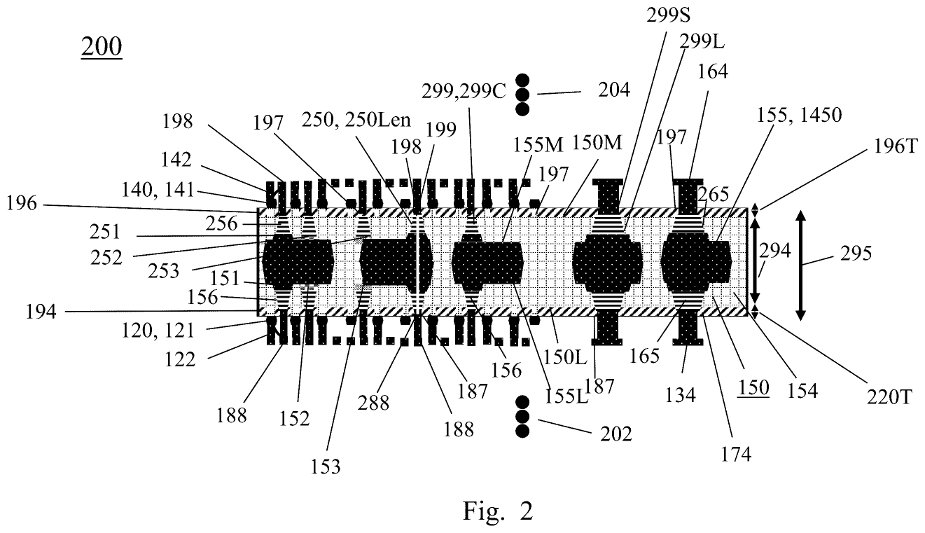

### Refer to FIGS. 1 and 2.

FIG. 1 is a cross-sectional view of an embodiment of a semiconductor memory chip or device 100, for example, a Static Random Access Memory (SRAM) 100, with a logic die 850, a memory die 1300, and their associated functions combined within one chip/device/wafer 100. The chip/device 100 has short device electrical connection paths, typically 250, between logic device connections, typically 122 (see FIG. 2), and memory device/cell connections, typically 142. The shorter connection paths 250 and a fewer number of through silicon vias (TSVs) 134/164 are enabled by a backside to backside (B2B) connection interface 150 disposed between the logic device connections 122 on the backside of the logic die 850 and memory device/cell connections 142 on the backside of the memory die 1300.

Some non-limiting examples of elements comprising different/alternative connection paths 250 comprise a logic device connection 122, a logic die backside interconnection 188, a logic backside contact 156, a logic conductive cap 151 (see FIG. 2), a logic dielectric cap 152/153, a logic RDL (see below), a memory device connection 142, a memory die backside interconnection 198, a memory backside contact 256, a memory conductive cap (typically 251), a memory dielectric cap (typically 252/253), a memory RDL (see below), a logic global via 134, a memory global via 164, and a logic global via contact 165, a memory global via contact 265. Other connective paths 250 are contemplated.

Each of the connection paths 250 has a connection path length 250Len.

In some embodiments, the chip/device 100 is mounted on a device substrate 105 that may include device substrate metallization layers 107 and components like resistors, capacitors, etc. One or more logic external contacts 127 and/or one or more memory external contacts 147 can be electrically connected to the device substrate 105 through substrate connections 108, like C4 bonds. In some embodiments, underfill material 109 is used to adhere the device/chip 100 to the device substrate 105 and/or provide stiffness and support.

FIG. 2 is a cross-sectional view of an embodiment of a B2B connection interface 150 with partial circuitry of the logic die 850 and a memory die 1300, i.e., some of the logic die and memory die circuitry is removed 202/204 for clarity.

The logic die 850 includes a logic device layer 120 that has a plurality of semiconductor logic devices, typically 121. Each of the logic devices 121 has one or more logic device connections, typically 122. Non-limiting examples of logic devices 121 with logic device connections 122 include: bipolar transistors (BJTs) 121 with emitter, base, and collector BJT logic device connections 122; field effect transistors (FETs) 121 with source, channel, and drain FET logic device connections 122; and diodes 121 with cathode and anode diode logic device connections 122, etc. Other logic devices 121 with their respective logic device connections 122 are contemplated.

The logic die 850 comprises a logic dielectric layer 194, like a logic shallow trench isolation (STI) layer 194. The logic dielectric layer 194 (logic STI layer 194) has a logic dielectric layer thickness 220T, a logic STI device surface/side 193, and a logic STI B2B connection interface side 195 (FIG. 1). The STI layer thickness 220T is about 150 nm or less, although other thicknesses are contemplated.

In non-limiting embodiments, the logic dielectric layer 194 (logic STI layer 194) is made of a dielectric material such as silicon dioxide or silicon nitride. The logic dielectric/STI layer 194 provides electrical isolation and prevents electric current leakage between the logic devices 121, logic device connections 122, and other metallization/conductive connections disposed on and through the logic dielectric/STI layer 194. Given the teachings herein, the skilled artisan can implement the logic dielectric/STI layer 194 using known materials and processes.

The logic dielectric/STI layer 194 electrically isolates some of the logic devices 121 and some of the logic device connections 122 from one another.

By known techniques, including epitaxial growing of semiconductor layers/circuitry, the logic device layer 120, the logic devices 121, and the logic device connections 122 are disposed/grown on the logic STI device surface side 193 of the logic STI layer 194.

The logic device layer 120 has a logic device layer thickness 120T (see FIG. 1) that ranges from 50 to 300 nanometers (nm) in thickness.

Some of the logic device 121 connections 122 connect to one or more logic die 850 backside interconnections, typically 188, that pass through and/or are in contact with the openings 187 (also referred to as logic openings 187) in the logic dielectric layer 194. In some embodiments, logic global vias 134 also pass through the logic openings 187.

The logic die backside interconnections 188, global vias 134/164, and other connections in these metalized layers are made of a conductive material, typically a metal, and more typically copper.

Further, a logic B2B interface side 195 of the logic dielectric/STI layer 194 is in direct contact with a logic side/surface 150L of the B2B connection interface 150 (discussed further below).

As stated, the dielectric/logic STI layer 194 has logic STI layer openings (layer openings), typically 187. Each of the logic die backside interconnections 188/122 passes from the logic die 850 backside (metalization) layers 126 and though one of the logic STI layer openings 187 so that there is a logic die backside interconnection 188 termination end 288 (see FIG. 2) exposed to (in contact with connections/backside contacts 156/165 within) the logic B2B interface side 195 of the logic STI layer 194. Note that, in some embodiments, logic global vias 134 vias pass through logic openings 187 to make contact with (conductive and/or optionally dielectric) backside contacts 165.

The memory die 1300 comprises a memory dielectric layer 196, like a memory shallow trench isolation (STI) layer 196. The memory dielectric layer 196 (memory STI layer 196) has a memory dielectric layer thickness 196T (FIG. 2), a memory STI device surface side 196A, and a memory STI B2B connection interface side 196B (FIG. 1). The STI layer thickness 196T is about 150 nm or less, although other thicknesses are contemplated.

In non-limiting embodiments, the memory dielectric layer 196 (memory STI layer 196) is made of a dielectric material such as silicon dioxide or silicon nitride.

By known techniques, e.g., epitaxial growth as above for the logic device layer 120, the memory device layer 140, the memory devices 141, and the memory device connections 142 are disposed on the memory STI device surface side 196A of the memory STI layer 196.

The memory STI layer 196 provides electrical isolation and prevents electric current leakage between some of the memory cells 141, memory cell connections 142, and other metalization/conductive connections disposed on and passing through the memory STI layer 196. Given the teachings herein, a skilled artisan can implement STI layer 196 using known materials and processes.

Further, the memory STI B2B connection interface side 196B is in direct contact with an interface memory side 150M of the B2B connection interface 150.

The memory STI layer 196 has memory STI layer openings (memory STI openings or memory openings), typically 197. Each of the memory die backside interconnections 198/142 passes though one of the memory openings 197 so that there is a memory die backside interconnection 198/142 termination end 199 (see FIG. 2) exposed on the memory STI B2B connection interface side 196B of the memory STI layer 196.

By known techniques, including epitaxial growing of semiconductor layers/devices, the memory device layer 140, the memory devices 141, and the memory device connections 142 are disposed/grown on the memory STI device layer surface side 196A of the memory STI layer 196.

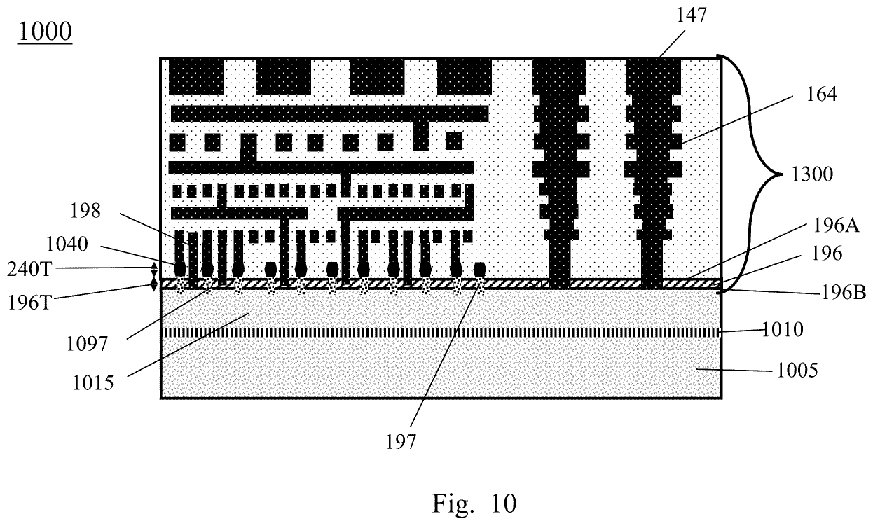

The memory device layer 140 has a memory device layer thickness 240T (see FIGS. 2 and 10) that ranges from 50 to 300 nm nanometers in thickness.

Non-limiting example memory devices/cells 141 in the memory device layer 140 include dynamic random access memory (DRAM), magnetoresistive random access memory, MRAM, and static random access memory (SRAM). Non-limiting examples of memory device/cell 141 connections 142 include random access memory (RAM) decoder connections. Other memory devices/cells 141 with their respective connections 142 are contemplated.

Further, a memory B2B interface side 196B of the memory dielectric/STI layer 196 is in direct contact with an interface memory side/surface 150M of the B2B connection interface 150 (discussed further below).

The memory dielectric/STI layer 196 has memory STI layer openings (memory openings), typically 197. Each of the memory die backside interconnections 198 and/or some of the memory device 141 connections 142 pass through and/or are in direct contact with one (or more) of the memory STI layer openings 197 so that there is a memory die backside interconnection 198 termination end (memory termination end 199) (see FIG. 2) exposed to (in contact with) a memory backside contact 256 within the memory interface side 196B of the memory STI layer 196. The memory backside contact 256 can be made of a conductive material (e.g., a metal, like copper) or a dielectric.

Note that, in some embodiments, some of the memory global vias 164 pass through the memory openings 197 in the memory dielectric/STI layer 196 to make contact with (a conductive and/or, optionally, dielectric, not shown,) memory global via backside contact 265.

In some embodiments, a memory backside contact 256 is connected to one or more of the memory die backside interconnections 198, e.g., the memory backside interconnection 198 memory terminal end 199, at/within the memory STI layer openings (memory openings), typically 197.

The memory die backside interconnections 198, memory device/cell 141 connections 142, and other connections (e.g., memory global vias 164), and the metalized layers in the memory die 1300 are made of a conductive material, typically metal, and more typically copper.

Without loss of generality, the terms “local via” and “global via” are now defined. A local via is defined as an electrical conductor, usually made of electrically conductive material, like a metal, e.g. copper, that vertically passes through one or more horizontal metalized layers, where the metalized layers passed through are close or “local” to the backside (B2B) connection interface 150. For example, local vias are located within the B2B connection interface 150 and the lower level backside metalization (logic or memory) layers 126/146. A logic local via would be located typically at or within the B2B connection interface 150 and/or the logic lower level backside 126 but not within the logic die 850 frontside 124. Likewise, a memory local via would be located typically at or within the B2B connection interface 150 and/or the memory die 1300 lower level backside 146 but not within the memory frontside 144. Non-limiting examples of logic local vias that pass through the logic STI layer openings 187 include the logic backside interconnection 188. Non-limiting examples of memory local vias that pass through the memory STI layer openings 197 include memory die backside interconnections 198. Other local vias are envisioned.

Alternatively, a global via is defined as an electrical conductor, usually made of electrically conductive material, like a metal, e.g. copper, that vertically passes through a large number of both backside and frontside horizontal metalized layers and generally into (and/or in contact with) the B2B connection interface 150 as well.

For example, the logic (memory) die 850 (1300) has logic (memory) global vias 134 (164) passing vertically through the logic (memory) die 850 (1300) backside 126 (146) into the logic (memory) die frontside 124 (144) and into the B2B connection interface 150, as well.

Generally, global via(s) 134/164 are larger in size than local vias (e.g. 188/198). Global vias 134/164 can distribute power to multiple power connections that are in one or more of the horizontal metalization layers (backside 126/146 and/or frontside 124/144) of the logic 850 (memory 1300) dies.

The logic (memory) global vias 134 (164) pass through (and/or are in contact with) logic STI openings 187 (memory STI openings 197) in the logic STI layer 194 (memory STI layer 196) and connect to one or more of the and backside RDL conductor(s) 1450, (logic RDL 155L and memory RDL 155M) as described in more detail below. Note that global vias 134/164 can also connect to/through backside contacts (e.g., logic global via backside contacts 165 or memory global via backside contacts 265, respectively.) In alternative embodiments the global via backside contacts 165 (logic) and 265 (memory), can be made from a conductive material (e.g., a metal, copper) or a dielectric.

The back-to-back connections are enabled by bonding a logic RDL 155L and a memory RDL 155M (see below) in the B2B connection interface 150 to produce a final backside RDL 1450 connection. Generally, the back-to-back connections reduce the number of global vias 134/164 needed and result in less crowded and less complicated connections in the final chip 100.

A backside to backside (B2B) connection interface 150 is disposed between the logic die 850 and the memory die 1300. The B2B connection interface 150 enables shorter connection paths 250 between the logic die 850 and memory die 1300 and enables fewer vias to pass through the logic die 850 and memory die 1300.

The B2B connection interface 150 has a B2B connection interface thickness 294 and has an interface logic side 150L and an interface memory side 150M. See FIG. 2. The interface logic side 150L and interface memory side 150M are opposite surfaces of the B2B connection interface 150. The interface logic side 150L interfaces (in some embodiments directly interfaces) with the logic STI layer 194 and the interface memory side 150M interfaces (in some embodiments directly interfaces) with the memory STI layer 196.

The B2B connection interface 150 is made from an electrically non-conductive material like interlayer dielectric (ILD). The B2B connection interface 150 includes other components and connections as described below.

The ILD making up part of the B2B connection interface 150 may be formed from, for example, a low-k dielectric material (with k<4.0), including but not limited to, silicon oxide, spin-on-glass, a flowable oxide, a high-density plasma oxide, borophosphosilicate glass (BPSG), or any combination thereof. The ILD is deposited by a deposition process, including, but not limited to chemical vapor deposition (CVD,) physical vapor deposition (PVD,) plasma enhanced CVD, atomic layer deposition (ALD), evaporation, chemical solution deposition, or like processes.

In some embodiments, the connection paths 250 passing through the B2B interface 150 include backside contacts. The backside contacts comprise one or more logic backside contacts, typically 156 and 165, and one or more memory backside contacts, typically 256 and 265, described in more detail, below. Some of the logic (memory) backside contacts 156 (256) are connected to one or more of the logic (memory) backside interconnections 188 (198), e.g., the logic (memory) backside interconnection 188 (198) terminal end 288 (199), at/within the respective logic (memory) opening 187 (197).

The B2B connection interface 150 also can comprise one or more backside contacts, comprising logic backside contacts, typically 156 (and logic global via backside contacts 165), and memory backside contacts, typically 256 (and memory global via backside contacts 265).

In some embodiments, the backside contacts are connected to vias. Some backside contacts 156/256 are connected to local vias, typically 188 (logic) and 198 (memory). Typically, local logic vias 188 are vertical connections/vias or logic die backside interconnections that connect to one or more logic device connections 122. Local memory vias 198 are typically vertical connections/vias that connect to one or more memory device connections 142. In some embodiments, the backside contacts directly connect to the logic/memory device connections 122/142.

On the other hand, global vias (logic global vias 134) and (memory global vias 164) are vias that typically pass through all or a large part of both the logic 850 and memory 1300 die. As stated, global vias are generally larger than local vias 188/198 and can distribute power, signals, etc. to many metalization layers throughout the dies 850/1300.

Some of these connection paths 250 comprise a logic device connection 122 connected to a logic die backside interconnection (local via) 188 (or directly), to a logic backside contact 156, to a respective backside redistribution layer (RDL) conductor 155, to a memory backside contact 256, and finally to a memory device connection 141. As described above, capping dielectric components (e.g., 152, 153, 252, 253) optionally are included in the connection path 250.

Alternative connection paths 250 include global vias 134/164. As a non-limiting example, a connection path 250 embodiment comprises a logic global via backside contact (made from conductive material) 165, a backside/completed RDL 1450, and a memory global via backside contact (made from conductive material) 265.

In some embodiments, a logic external contact 127 and a logic global via 134 and/or a memory global via 164 and a memory external contact 147 are connected to this connection path 250.

As already disclosed, alternative embodiments of logic (memory) backside contacts 156/165 (256/265) are contemplated. In some embodiments these logic/memory backside contacts are made of conductive material like metal, e.g. copper 151/165. In alternative embodiments, these logic/memory backside contacts 156/165/256/265 are capped with dielectrics.

Further, non-limiting embodiments comprise a combination of conductive and dielectric materials (as backside contacts and/or dielectric caps), e.g., 156/151, 156/152, 156/153 as connected to logic die circuitry, e.g., 188/288/134. For example, the connection path 250 may include a logic backside contact 156 made of metal (or dielectric) in electrical series with a logic metal cap 152. Alternatively, the connection path 250 may include the logic backside contact 156 made of metal in electrical series with a logic dielectric cap 152 or 153, each made from a different dielectric material.

The B2B connection interface 150 further comprises one or more memory backside contacts, typically 256. For example, the connection path 250 may include a memory backside contact 256 made of metal in electrical series with a memory metal cap 251. Alternatively, the connection path 250 may include the memory backside contact 256 made of metal, like copper, in electrical series with a memory dielectric cap 252 and/or 253, each made from the same or a different dielectric material.

Given this disclosure, one skilled in the art would recognize multiple combinations of logic/memory backside contacts and caps made from different materials in a manner that would alter the electrical characteristics of the connection path 250. These combinations are contemplated by the invention.

Refer again to FIG. 2. It is noted that embodiments of the backside contacts have a non-uniform shape. Embodiments of these backside contacts comprise any of the logic backside contacts 156, memory backside contacts 256, logic global via backside contacts 165, and memory global via backside contacts 265—in aggregate, backside contacts, typically 299.

In some embodiments, the backside contacts 299 have cross-sections 299C that is non-uniform, e.g. are tapered, so that one part of the cross-section of the (logic and/or memory) backside contacts 299 is smaller 299S than a larger cross-section 299L of other parts of the respective backside contact 299.

In some embodiments, the smaller cross-section 299S of the backside contact 299 (partially or fully) passes through (and/or is in direct contact with) one of the logic/memory openings 187/197 in the logic/memory STI 194/196 to make the electrically connection with one or more of the logic/memory device connections 122/142 of the associated logic/memory devices 121/141. These connections 122/142 can be made through local via connections, like the logic die backside interconnection 188 (and conductive termination end 288), and/or the memory die back side interconnection 198 (and conductive termination end 199).

In some embodiments, the larger cross-section 299L of the backside contacts 299 are within the B2B interface 150. In some embodiments, these larger cross-section surfaces 299L of the logic backside contacts 156 are electrically connected and bound to a logic side 155L of a RDL 155/1450 and the larger cross-section surfaces 299L of the memory backside contacts (e.g., 256/265) are electrically connected and bound to a memory side 155M of the RDL 155/1450. As mentioned, the logic RDL 155L and the memory RDL 155M are bound together and electrically connected, e.g., by hybrid bonding, to form a backside redistribution layer or conductor (RDL 155/1450) within the B2B interface and to complete one of the connection paths 250 between one or more logic connections 121 and one or more memory connections 142 or to complete connection paths 250 between one of the logic global vias 134 and one of the memory global vias 164.

In some embodiments, the dielectric caps, e.g. logic dielectric caps 152/153, are between the logic backside contacts 156 and the logic side RDL/logic RDL 155L of the RDL 1450 within the B2B interface 150. Again, different dielectric cap materials can be selected for these dielectric caps, e.g., 152/153, in order to individually modify the electrical characteristics of a particular connection path 250. Alternatively, cap materials are made of a conductive/metallic material, e.g. copper 151.

In some embodiments, in a similar manner, the dielectric caps, e.g., memory dielectric caps 252/253, are between the memory backside contacts 256 and the memory side/memory RDL 155M of the backside RDL 155/1450. Again, different dielectric cap materials are selected for these memory dielectric caps, e.g., 252/253. in order to individually modify the electrical characteristics of a particular connection path 250. Alternatively, cap materials are made of a conductive/metallic material, e.g. copper 251.

In a similar manner, connection paths 250 are formed when a logic global via 134 is connected through a logic global via backside contact 165, through an RDL 155/1450 (e.g., through the electrically connected logic side of the RDL 155L and memory side of the RDL 155M) to a memory global via backside contact 265, and then to a memory global via 164. The logic global via backside contact 165 and the memory global via backside contact 265 are made of a conductive material, e.g., a metal like copper. Alternatively, as disclosed above, dielectric caps (not shown) of different dielectric materials, can be placed in the connection path 250 between the logic (memory) global via backside contact 165 (265) and the RDL 155/1450.

The RDL conductors 1450 can function as connections and/or conductive lines and are made of a conductive material, like a metal, e.g. copper. The backside RDL conductors 1450 are conductive lines and/or pads that provide the ability to carry out electrical distribution and make available electrical connections to components and/or connections, like device connections 122/142, at different locations on the die.

Using the B2B connection interface 150 shortens the connection paths 250 because the logic device connections 122 and the memory device connections 142 are in close proximity. As such, the plurality of connection paths 250 will each have a connection path length 250Len shorter than the sum 295 of the logic STI thickness 220T, the logic device layer thickness 120T, the B2B connection interface thickness 294 of the B2B connection interface 150, the memory STI layer thickness 196T of the memory STI layer 196, and the memory device layer thickness 240T. In some embodiments, the connection path 250 lengths 250Len will be between 600 nm and 1200 nm, in any event, less than 1.2 μm. The shorten connection paths through the B2B interface 150 enable faster communication between the logic 850 and memory 1300 dies and simpler and less dense circuitry within the memory device/chip 100.

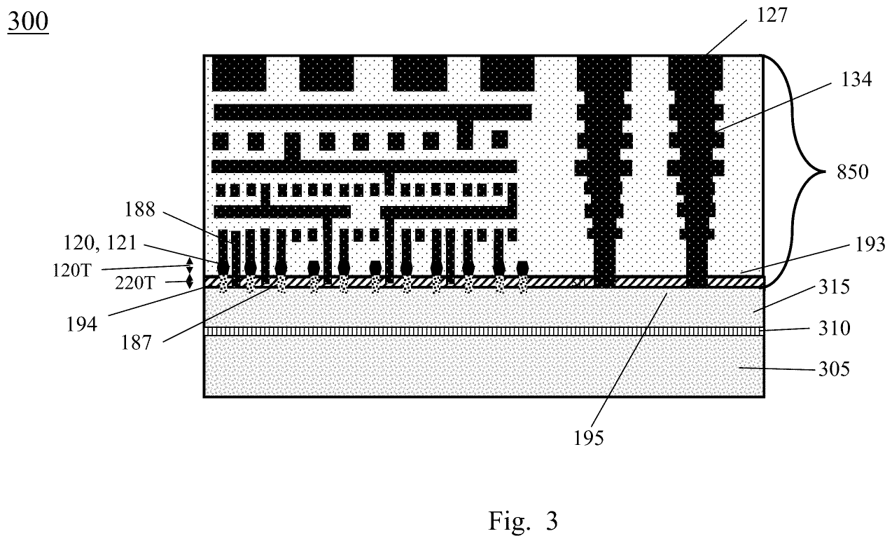

FIG. 3 is a cross-sectional view of an embodiment of an interim structure 300 where a logic die 850 is disposed on interim substrates 305/315 and further showing the logic die 850 with logic local vias (logic die backside interconnections), typically 188, and logic global vias, typically 134, connected through logic openings, typically 187, through a logic dielectric layer, e.g., a logic shallow trench isolation (STI) layer 194. Logic global vias 134 also pass through logic openings 187 in the logic STI layer 194.

The interim logic structure 300 is made by disposing a etch stop layer 310 onto a substrate 305. The substrate 305 is made of any known substrate material used in semiconductor processing but is some embodiments the substrate 305 is made of silicon (Si).

The etch stop layer 310 is disposed on the substrate 305 by known deposition methods. Non-limiting examples of deposition methods include atomic layer deposition (ALD), chemical vapor deposition (CVD), Plasma Enhanced Chemical Vapor Deposition (PECVD), Radio Frequency Chemical Vapor Deposition (RFCVD,) Physical Vapor Deposition (PVD), Pulsed Laser Deposition (PLD), Liquid Source Misted Chemical Deposition (LSMCD), and/or sputtering.

In some embodiments, the etch stop layer 310 is made of silicon-germanium (SiGe).

An epitaxial substrate layer 315 is disposed on the etch stop layer 310 by any one of the known deposition methods disclosed above. In some embodiments, the epitaxial substrate layer 315 is made of Si.

The logic dielectric layer 194, e.g., a logic shallow trench isolation (STI) layer 194, is disposed on the epitaxial substrate layer 315 using known methods, e.g., as disclosed above. The logic dielectric layer 194 has a logic dielectric layer thickness 220T, a logic STI device surface/side 193, and a logic STI B2B connection interface side 195. The STI layer thickness 220T is about 150 nm or less, although other thicknesses are contemplated. In some embodiments, the logic dielectric layer thickness 220T is controlled by the deposition method, for example, by ALD. Other known methods of controlling the logic dielectric layer thickness 220T are contemplated.

Logic openings, typically 187, are made through the logic dielectric layer 194. The logic openings are located in the logic dielectric layer 194 where connections like logic backside interconnections 188, logic device connections 122, logic global vias 134, and/or other connections will pass through (or will be connected to connections that pass though) the logic dielectric layer 194.

The logic openings 187 are made using standard semiconductor processes known to those skilled in the art. Non-limiting examples include penetration/ablation with lasers, masking and etching lithography, etc.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by source gases are controlled and the system parameters are set so that the deposited atoms arrive at the deposition surface of the semiconductor substrate with sufficient energy to move around on the surface and orient themselves to the crystal arrangement of the atoms of the deposition surface. Therefore, each semiconductor layer of the epitaxial semiconductor material stack/layer 120 (and other structures in 850) has the same crystalline characteristics as the deposition surface 193/194 on which it is formed. Epitaxially growth/growing is well known to those skilled in the art.

The logic die 850 is epitaxially grown upon the logic dielectric layer 194 surface 193. The logic device layer 120, with the logic device layer thickness 120T, is the first layer(s) epitaxially grown on the logic dielectric layer 194. Connections on and within the logic dielectric layer 194 are grown over the respective logic openings 187 through to which back-to-back (B2B) connections will be made. Non-limiting examples of these connections include: logic backside interconnections 188, logic device connections 122, and logic global vias 134.

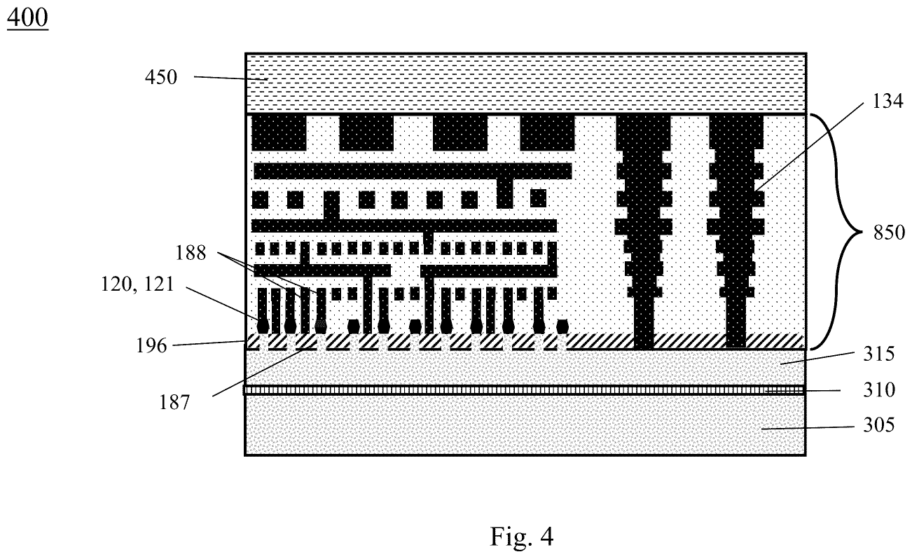

FIG. 4 is a cross-sectional view of an embodiment of an interim structure 400 of a logic die 850 disposed on interim logic substrates 305/310/315, as shown in FIG. 3, with an interim logic device handler/carrier 450 attached. Handlers (or carriers) 450 are known attachments to chips, wafers, or dies that are used to pick, place, flip, align, rotate, and/or otherwise handle the dies (or interim structures, e.g. 400/850) to which the handlers 450 are attached. Handlers 450 can also provide stiffness and support to the die/structure being handled. Handlers typically are made from a strong, non-flexible material like a semiconductor/silicon or a dielectric material. Handlers 450 are attached to the die, e.g. the logic die 850 (or related interim structure 300), by adhesives and are removed later by applying a solvent to the adhesive. Some adhesives are removed by light energy of a certain frequency (e.g., ablated by a laser) that can be applied through a transparent handler 450 in order to release the handler 450. One skilled in the art is knowledgeable about the selection, attachment, use, and removal of a handler 450 from a die/structure.

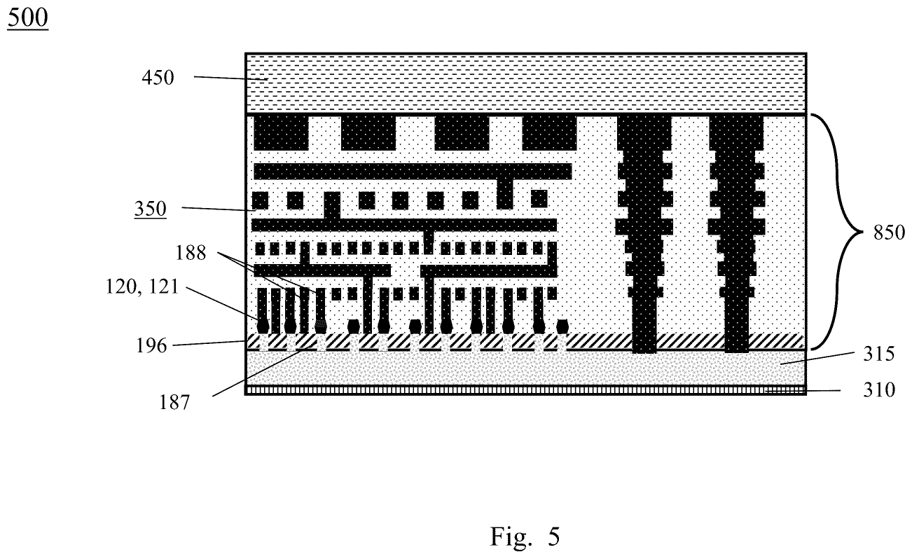

FIG. 5 is a cross-sectional view of an embodiment of the interim structure 500 of the logic die 850 shown in FIG. 4, disposed on the interim epitaxial substrate 315 of FIG. 4 after one of the interim substrates 305 is removed.

For example, the logic die 850 is moved/positioned by the handler 450 to a location/position where substrate 305 is removed by one or more known process steps. For instance, a chemical/mechanical processing (CMP) is applied to remove the substrate 305 until the material being polished (from substrate 305) includes the material (e.g., SiGe) in the stop layer 310. Once the stop layer 310 material is detected, the CMP is terminated. Alternatively, the substrate 305 is removed by a chemical etch that selectively removes the substrate 305 material (e.g., Si), but does not remove the stop layer 310 material (e.g., SiGe). CMP and chemical etching are processes known to one skilled in the art.

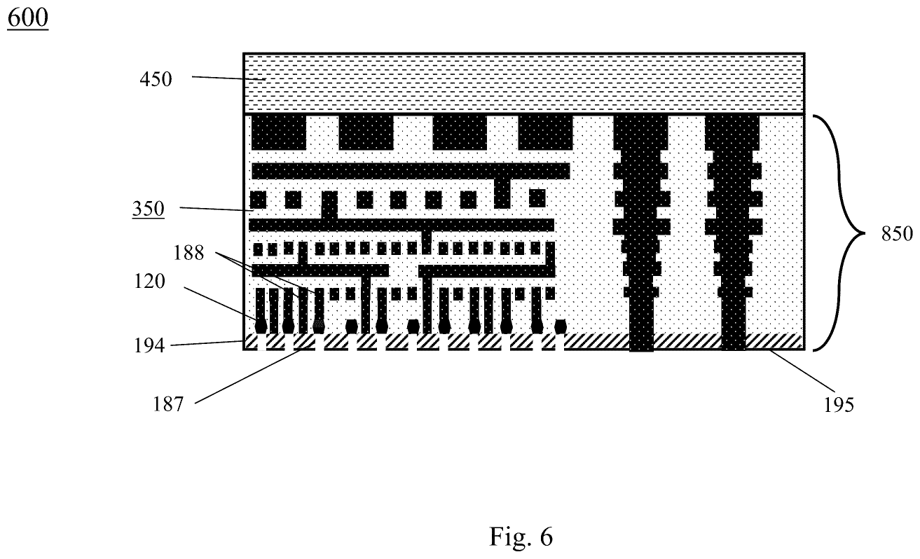

FIG. 6 is a cross-sectional view of an embodiment of the interim structure 600 of the logic die 850 of FIG. 5 with the stop layer 310 and/or the remainder of the other interim substrates (e.g., the epitaxial substrate layer 315) removed. Further, any remaining material within the logic openings 187 is removed so that the logic openings 187 provide a clear, open passage and access from logic device layer 120, through the logic STI layer/logic STI 194, and to the B2B connection interface side 195.

As before, the stop layer 310 can be removed by a CMP and/or a chemical etch that is selective to the material in the stop layer 310 (e.g., SiGe).

In some embodiments, a chemical etch, selective to the material of the epitaxial substrate 315, e.g., Si, removes the epitaxial substrate 315. Again, the selective etching removes any material from within the logic openings 187.

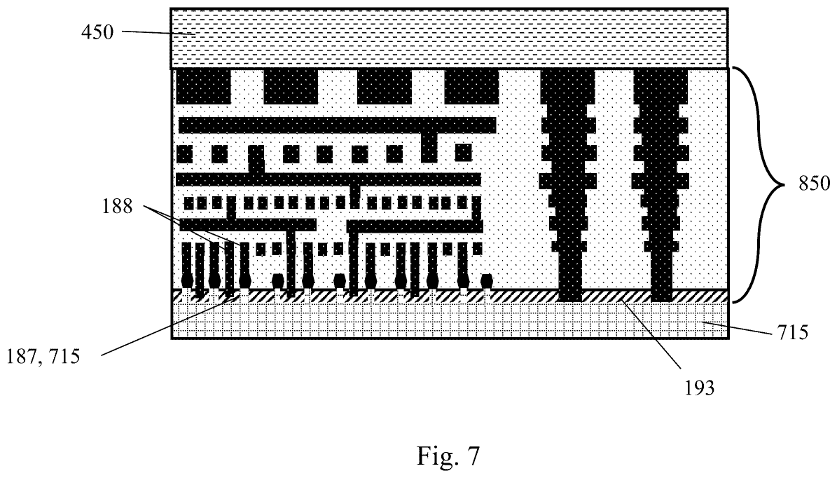

FIG. 7 is a cross-sectional view of an embodiment of an interim structure 700 of a logic die 850 (as shown in FIG. 6) with a partially formed logic partial interlayer dielectric (ILD) 715, where the ILD dielectric fills one or more logic openings 187 in the logic STI layer 194.

The logic partial ILD 715 is made from, as a non-limiting example, a low-k dielectric material (with k<4.0), including but not limited to, silicon oxide, spin-on-glass, a flowable oxide, a high-density plasma oxide, borophosphosilicate glass (BPSG), or any combination thereof. The logic partial ILD 715 is deposited by a deposition process, including, but not limited to chemical vapor deposition (CVD,) physical vapor deposition (PVD,) plasma enhanced CVD, atomic layer deposition (ALD), evaporation, or chemical solution deposition. Other like processes are contemplated.

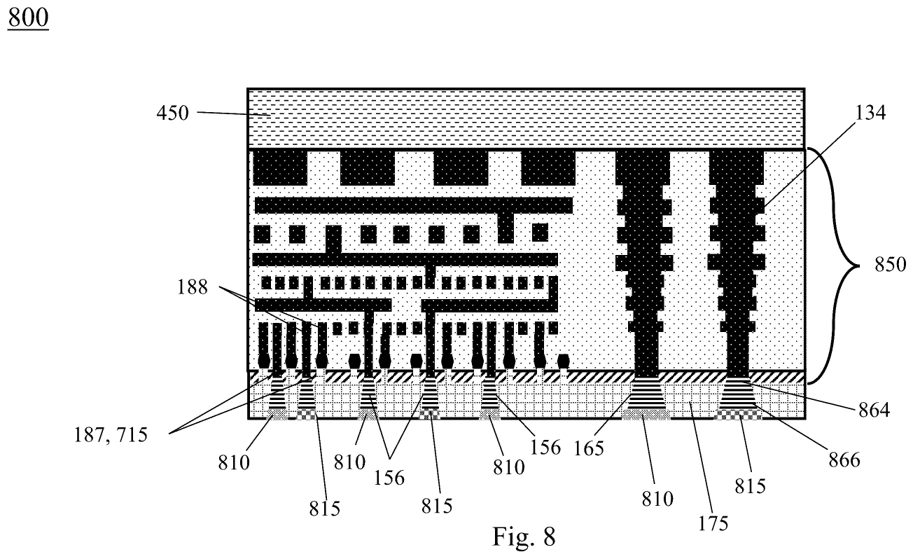

FIG. 8 is a cross-sectional view of an embodiment of the interim logic die structure 800 shown in FIG. 7 with (tapered) logic backside contacts, typically logic backside contacts 156 and logic global via backside contacts 165, formed in a logic partial ILD 715 and where each of the (smaller cross-section parts, typically 864, of the) logic backside contacts 156 and logic global backside contacts 165 connect to one or more logic backside interconnects by passing through (or being in direct contact with) one of the logic connection openings 187 of the logic STI layer 196 and, further comprising, within the logic ILD, optional logic dielectric caps 810/815 that are disposed on a larger cross-section part, typically 866, of one or more of the backside contacts (logic backside contacts 156 and/or logic global backside contacts 165).

Note that in some embodiments, the logic backside contacts 156 and/or the logic global backside contacts 165 are made of a conductive material, e.g., a metal like copper. Furthermore, in some embodiments, some of the logic backside contacts have dielectric caps 810/815 made of different dielectric material disposed on different of the logic backside contacts 156/165.

However, in alternative embodiments of the logic backside contacts 156/165, not shown, there is no dielectric cap. In these embodiments, the entire logic backside contact 156/165 is made of a conductive material.

Note that the non-uniform shape of the logic global backside contacts 156/165 (for example a conical or pyramidal shape) permits the smaller cross-sectional area, typically 864, to pass (either partially or fully) through the logic openings 187 in order to make physical and electrical contact with any electrical connection, e.g., a logic local via, typically 188, a logic device interconnection, typically 122, or a logic global via 134, etc. that is in proximity, or partially through. or fully through the respective logic opening 187.

In addition, the larger cross-sectional area, typically 866, of the logic backside contacts 156/165 affords a larger surface for contact to connections made in later process steps, as described below. In some embodiments, the logic dielectric caps 810/815 are disposed on the larger cross-section part, typically 866, of the respective logic backside contact 156/165, so that the logic dielectric caps 810/815 will have a larger cross-section area for a later contact surface as well.

In one or more embodiments, backside contacts/vias 156/165 are formed by conventional patterning and metallization processes. After that, metals can be recessed and capped with dielectric 810/815. In some embodiments, two separate masks can be used to carry out metal recess processing so two different cap materials can be formed sequentially.

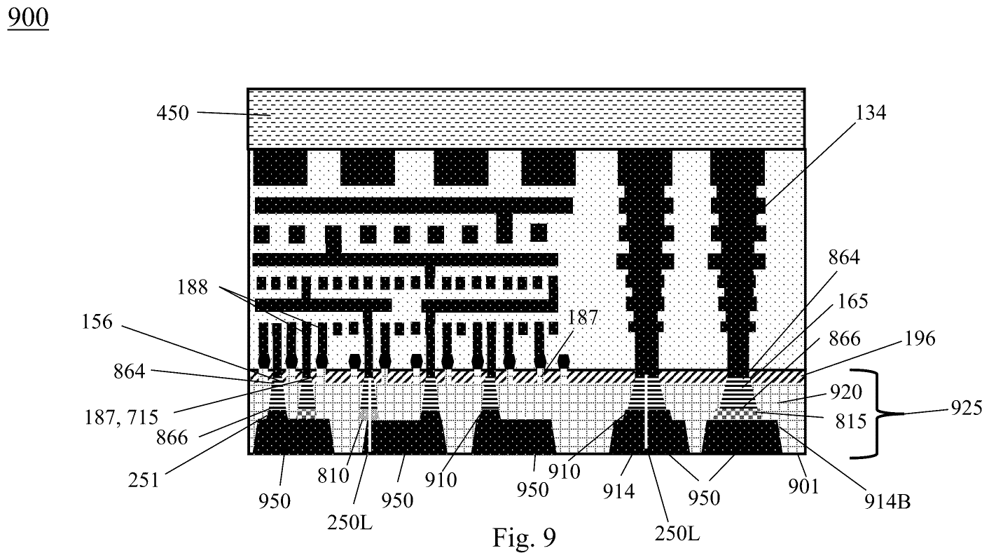

FIG. 9 is a cross-sectional view of an embodiment of a logic die 900 with a logic part of a B2B connection interface (logic interface) 925 containing a completed logic interlayer dielectric (logic ILD) 920 with one or more logic redistribution layer (logic RDLs) 950 conductors within the logic ILD 920. One or more of the logic RDL 950 conductors connects to a larger cross-section part, typically 866, of one or more of the logic backside contacts 156/165, respectively. In some embodiments, the logic RDL 950 conductor connects to the larger cross-section 866 through an optional dielectric cap 810/815. In other embodiments, the logic RDL 950 conductor connects to the larger cross-section 866 of the respective logic backside contact 156/165 through a conductive layer, e.g., a metal, like copper 910. Alternatively, the logic RDL 950 conductor connects to/through one or more dielectric caps 810/815 and one or more conductive layers 910. (Note again that the different reference numbers 810 and 815 indicate that the dielectric caps 810/815 can be made from different types of dielectric material.) In some embodiments, the logic backside contacts 156/165 connect to a logic RDL backside contact side 914B of the logic RDL 950, opposite the logic bonding surface 914 of the logic RDL 950.

Each of the logic backside contacts 156/165 has a smaller cross-section part 864 that passes through (and/or in direct contact with) one of the logic connection openings 187 in the logic STI 196 to connect with one or more logic backside interconnects (e.g., a logic local via, typically 188, a logic device interconnection, typically 122, or a logic global via 134, etc.) to form a partial (logic) connection path (i.e., a logic part of the connection path 250L). Some of these logic connection paths comprise one or more optional (logic) dielectric caps 810/815.

It is noted that in some embodiments, the logic ILD 920 is thicker than the logic partial ILD 715 after more ILD was deposited using the methods disclosed above.

In one embodiment, a second layer of ILD is disposed upon the logic partial ILD 715 to achieve the thickness of the completed logic ILD 920. Then, by a series of lithographic steps, spaces in the logic ILD 920 are etched away so that the conductive layers 910 and/or dielectric caps 810/815 are deposited on the larger cross-sections 866 of one or more of the backside contacts (logic backside contacts 156 and/or logic global backside contacts 165). Then the logic RDLs are deposited 950.

These lithographic steps, e.g., masking, etching, and deposition are known to those skilled in the art. Example deposition techniques are disclosed above.

Note that the logic RDLs 950 have a logic bonding surface 914 that in some embodiments is coplanar with the logic ILD 920 bottom surface 901. This coplanarity can be achieved by performing a CMP step after the logic RDLs 950 are deposited.

The logic RDL bonding surface 914 is a surface of the conductive material/metal/copper from which the logic RDL 950 is made. As disclosed in more detail below, the logic RDL bonding surface 914 will be physically and electrically bonded, e.g., by hybrid bonding, to a corresponding memory RDL bond surface (see below) to form a completed RDL 1450.

In some embodiments, the logic RDL bonding surface 914 has a larger area than any other cross-sectional area of the logic RDL 950. In these embodiments, the logic RDL has a non-uniform cross-sectional area, e.g., the logic RDL 950 has a tapered shape. The larger area of the RDL bonding surface 914 enables the logic RDL 950 to electrically connect with the memory RDL bond surface to reduce connection resistance of the bonding and to reduce the chance of a bad connection because of positional off sets (misalignment) between the bonding surfaces of the logic RDL 950 and the memory RDL. See more disclosure below.

The following description of FIGS. 10 through 13 explain the memory die 1300 structures and how the memory die 1300 is made. In some embodiments, the memory die 1300 is made in a similar way as the logic die 850, as explained above.

FIG. 10 is a cross-sectional view of an embodiment of an interim structure 1000 of a memory die 1300 with both memory backside (e.g. local) interconnections (e.g., 198, typically) and memory global connections (e.g., 164, typically) connected through and/or direct contact with memory connection openings 197, typically, in a memory shallow trench isolation (STI) layer (a memory dielectric layer) 196. The memory die 1300 is disposed on interim memory substrates 1005/1015.

The interim memory structure 1000 is made by disposing an etch stop layer 1010 onto a memory substrate 1005. The memory substrate 1005 is made of any known substrate material used as a substrate in semiconductor processing but, in some embodiments, the memory substrate 1005 is made of silicon (Si).

The etch stop layer 1010 is disposed on the memory substrate 1005, e.g., by known deposition methods. Non-limiting examples of deposition methods include ALD, CVD, PECVD, RFCVD, PVD, PLD, LSMCD, and/or sputtering.

In some embodiments, the etch stop layer 1010 is made of silicon-germanium (SiGe).

A memory epitaxial substrate layer 1015 is disposed on the etch stop layer 1010 by known deposition methods and processes. In some embodiments, the memory epitaxial substrate layer 1015 is made of silicon.

A memory dielectric layer 196, e.g., a memory shallow trench isolation (STI) layer 196, is grown on the epitaxial substrate layer 1015 by known epitaxial and/or lithographic methods. The memory dielectric layer 196 has a memory dielectric layer thickness 196T, a memory STI device surface/side 196A, and a memory STI B2B connection interface side 196B. The memory STI layer thickness 196T is about 150 nm or less, although other thicknesses are contemplated.

In some embodiments, the memory dielectric layer thickness 196T is controlled by the deposition/growth, polishing, and/or etching processes. Other known methods of controlling the memory dielectric layer thickness 196T are contemplated. In some embodiments the memory dielectric layer 196 is made of silicon dioxide and/or silicon nitride.

Memory openings, typically 197, are made through the memory dielectric layer 196. The memory openings 197 are located in the memory dielectric layer 196 where connections like memory backside interconnections 198, memory device connections 142, memory global vias 164, and/or other connections will pass through (or will be connected to connections that pass though) the memory dielectric layer 196.

The memory openings 197 are made using standard semiconductor processes known to those skilled in the art. Non-limiting examples include penetration/ablation with lasers, masking and etching lithography, etc.

The memory die 1300 (including the memory device layer(s) 140) is epitaxially grown upon the memory STI device surface/side 196A. The memory device layer 140, with the memory device layer thickness 140T, is the first layer(s) epitaxially grown on the memory dielectric layer 196 memory STI device surface side 196A. Connections on and within the memory dielectric layer 196 are grown over and/or through the respective memory openings 197 through which back-to-back connections will be made, as disclosed below. Non-limiting examples of these back-to-back connections comprise: memory backside interconnections 198, memory device connections 142, and memory global vias 164.

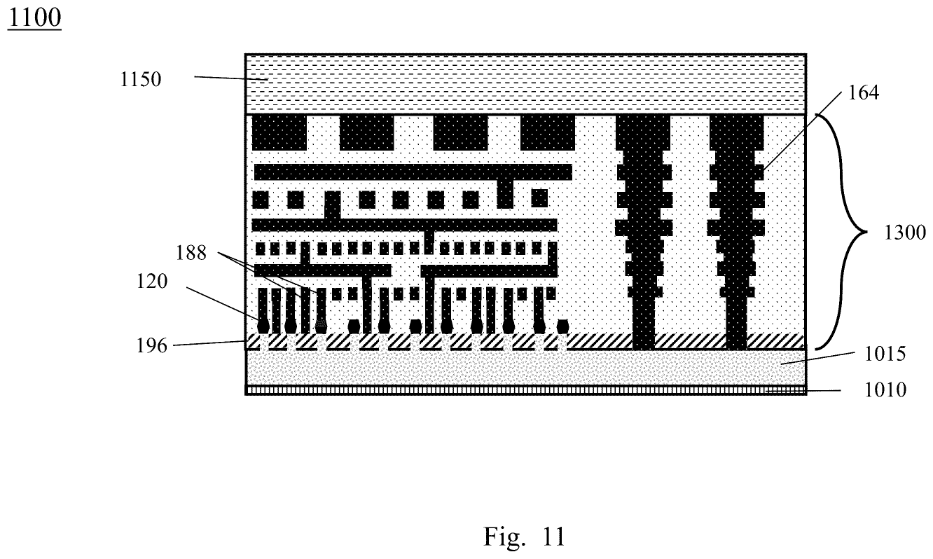

FIG. 11 is a cross-sectional view of an embodiment of an interim structure 1100 of memory die 1300 with some interim memory substrates 1115 attached, an interim memory device handler/carrier 1150 attached, and one of the interim substrates 1005 (shown in FIG. 10) removed.

For example, the memory die 1300 is moved/positioned by the handler 1150 to a location/position where substrate 1105 is removed by one or more known process steps. In some embodiments, a chemical-mechanical planarization (CMP) is applied to remove the substrate 1105 until the material being polished (from substrate 1105) includes the material (e.g., SiGe) in the stop layer 1010. Once the stop layer 1010 material is detected, the CMP is terminated. Alternatively, the substrate 1005 is removed by a chemical etch that selectively removes the substrate 1005 material (e.g., Si), but does not remove the stop layer 1010 material (e.g., SiGe). CMP and chemical etching are processes known to one skilled in the art.

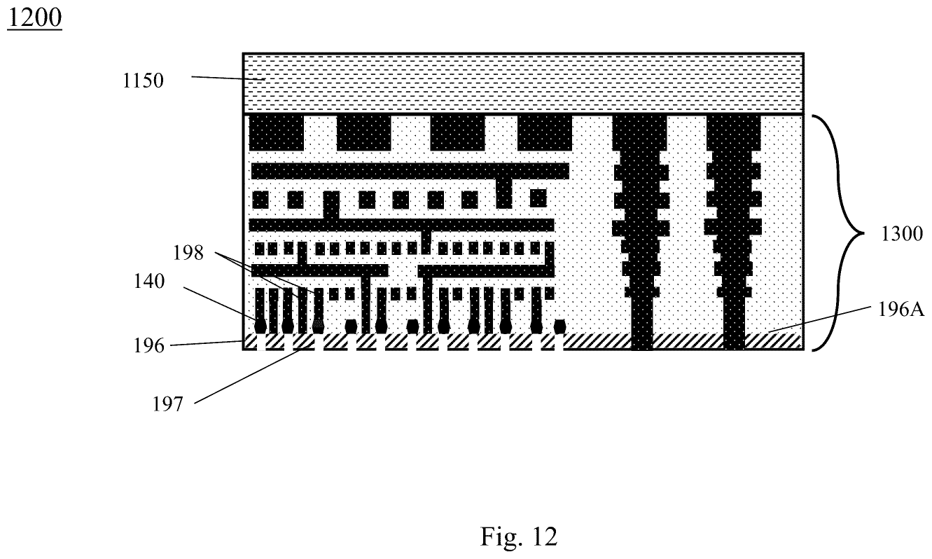

FIG. 12 is a cross-sectional view of an embodiment of the interim structure 1200 of the memory die 1300 with all of the remaining interim memory substrates/stop layers 1010/1015 of FIG. 11 removed and showing the memory openings 197 in the memory STI (the memory dielectric layer) 196 void of any material.

Material within the memory openings 197 is removed so that the memory openings 197 provide a clear, open passage through the memory STI layer 196 to the memory STI device surface side 196A.

In some embodiments, a chemical etch, selective to the material, e.g., silicon (Si), of the memory epitaxial substrate 1015, removes the memory epitaxial substrate 1015. Again, the selective etching removes any material from within the memory openings 197.

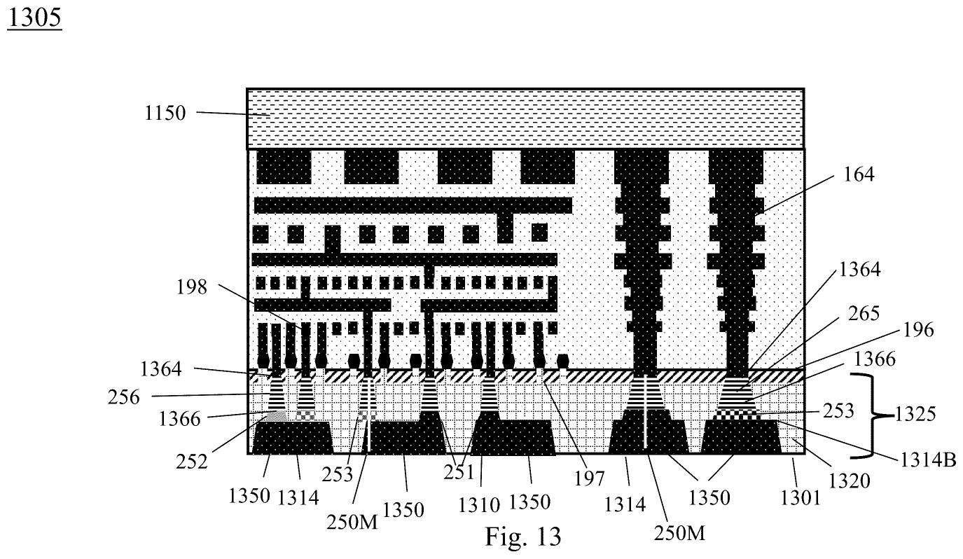

FIG. 13 is a cross-sectional view of an embodiment of the interim memory die structure 1200 shown in FIG. 12 with (tapered) memory backside contacts 256/265, typically memory backside contacts 256 and memory global via backside contacts 265, formed in a memory partial ILD 1320 and where each of the (smaller cross-section parts, typically 1364, of the) memory backside contacts 256 and memory global backside via contacts 265 connects to one or more memory backside interconnects 198 or memory global vias 164 by passing through (or being in contact with) one of the memory connection openings 197 of the memory STI layer 196. Within the memory ILD 1320, optional memory dielectric caps 252/253 are disposed on a larger cross-section part, typically 1366, of one or more of the backside contacts (memory backside contacts 256 and/or memory global backside contacts 265).

Note that in some embodiments, the memory backside contacts 256 and/or the memory global backside contacts 265 are made of a conductive material, e.g., a metal, like copper. Furthermore, in some embodiments, some of the memory backside contacts have dielectric caps 252/253 made of different dielectric material disposed on different of the memory backside contacts 256 and/or 265.

However, in alternative embodiments of the memory backside contacts 256 and/or 265, there is no dielectric cap. In these embodiments, the entire memory backside contact 256/265 is made of a conductive material or may have a conductive (e.g., metallic) cap 251.

Note that the non-uniform shape of the memory global backside contacts 256/265, for example a conical or pyramidal shape, permits the smaller cross-sectional area, typically 1364, to pass (either partially or fully) through the memory openings 197 in order to make physical and electrical contact with any electrical connection, e.g., a memory local via, typically 198, a memory device interconnection, typically 142, or a memory global via 164, etc. that is in proximity, or partially through, or fully through the respective memory opening 197.

In addition, the larger cross-sectional area, typically 1366, of the memory backside contacts 256/265 affords a larger surface for contact for connections made in later process steps, as described below. In some embodiments, the memory dielectric caps 252/253 are disposed on the larger cross-section part, typically 1366, of the respective memory backside contact 256/265, so that the memory dielectric caps 252/253 will have a larger cross-section area for a later contact surface as well.

FIG. 13 further shows a memory part of a B2B connection interface (memory interface) 1325 containing a completed memory interlayer dielectric (memory ILD) 1320 with one or more memory redistribution layer (memory RDLs) 1350 conductors within the memory ILD 1320. Each of the memory RDL 1350 conductors connects to a larger cross-section part, typically 1366, of one or more of the memory backside contacts 256/265, respectively. In some embodiments, the memory RDL 1350 conductor connects to the larger cross-section 1366 through an optional dielectric cap 252/253. In other embodiments, the memory RDL 1350 conductor connects to the larger cross-section 1366 of the respective memory backside contact 256/265 through a conductive layer, e.g., a metal, like copper 251. Alternatively, the memory RDL 1350 conductor connects to/through one or more dielectric caps 252/253 and one or more conductive layers 251, i.e., the memory RDL 1350 has multiple connections 253/251. In some embodiments, the memory backside contacts 256/265 connect to a memory RDL backside contact side 1314B of the memory RDL 1350, opposite the memory bonding surface 1314 of the memory RDL 1350.

Each of the memory backside contacts 256/265 has a smaller cross-section part 1364 that passes through (and/or is in direct contact with) one of the memory connection openings 197 in the memory STI 196 to connect with one or more memory backside interconnects (e.g., a memory local via, typically 198, a memory device interconnection, typically 142, or a memory global via 164, etc.) to form a partial (memory) connection path through the memory RDL 1350 (a memory part 250M of the connection path 250). Some of these memory connection paths 250M comprise one or more optional (memory) dielectric caps 252/253.

It is noted that in some embodiments, the memory ILD 1320 is thicker than the memory partial ILD, not shown. The thickness of the memory ILD 1320 is increased by adding more layer(s) of ILD, similar to what was done to the logic partial ILD 715 as described in FIG. 9.

In one embodiment, a second layer(s) of ILD is disposed upon the memory partial ILD to achieve the thickness of the completed memory ILD 1320. Then, by a series of lithographic steps, spaces in the memory ILD 1320 are etched away in which the backside memory contacts 256/265 are deposited. Then the conductive layers 251 and/or dielectric caps 252/253 are deposited on the larger cross-sections 1366 of one or more of the backside contacts (memory backside contacts 256 and/or memory global backside contacts 265). Afterwards, the memory RDLs 1350 are deposited.

These lithographic steps, e.g., masking, etching, and deposition are known to those skilled in the art. Example deposition techniques are disclosed above.

Note that the memory RDLs 1350 have a memory bonding surface 1314 that in some embodiments is coplanar with the memory ILD 1320 bottom surface 1301. This coplanarity can be achieved by performing a CMP step after the memory RDLs 1350 are deposited.

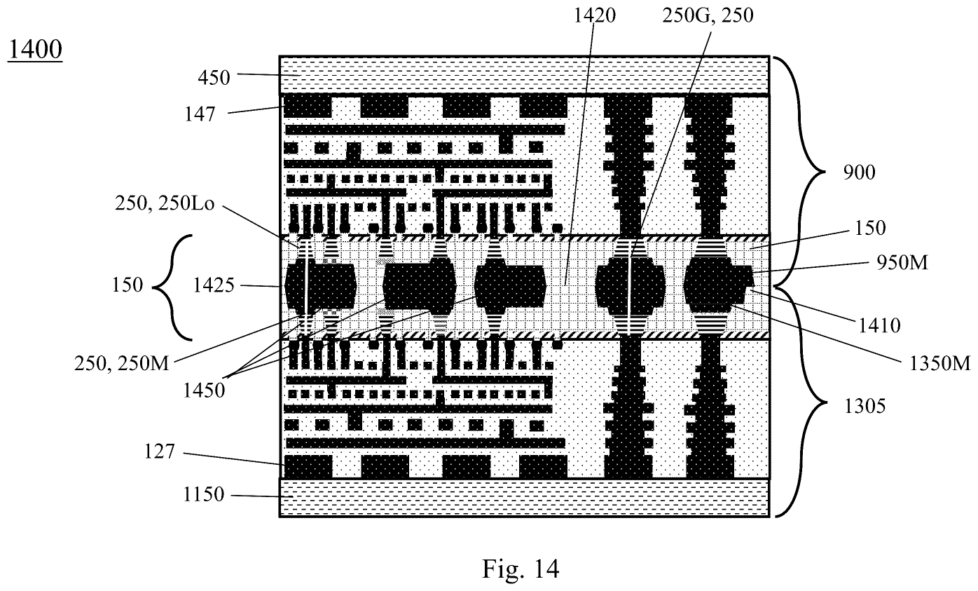

The memory RDL 1350 bonding surface 1314 is a surface of the conductive material/metal/copper from which the memory RDL 1350 is made. As disclosed above, the memory RDL bonding surface 1314 will be physically and electrically bonded, e.g., by hybrid bonding, to a corresponding logic RDL bond surface 914 (see above) to form a completed RDL 1450 (see FIG. 14).

In some embodiments, the memory RDL bonding surface 1314 has a larger area than any other cross-sectional area of the memory RDL 1350. In these embodiments, the memory RDL has a non-uniform cross-sectional area, e.g., the memory RDL 1350 has a tapered shape. The larger area of the memory RDL bonding surface 1314 enables the memory RDL 1350 bonding surface 1314 to electrically connect with the logic RDL bond surface 914 with reduced connection resistance from the bonding and to reduce the chance of a bad connection because of positional off sets (misalignment) between the bonding surfaces of the logic RDL 950 and the memory RDL 1350.

FIG. 14 is a cross-sectional view of an embodiment of a memory device, e.g., a SRAM device structure 1400, that is a combination of a logic die 850 (including logic handler 450 and logic interface 925, i.e., embodiment 900) and memory die 1300 (including memory handler 1150 and memory interface 1325, i.e., embodiment 1305), where the logic die 850 and memory die 1300 are connected back-to-back (B2B) to form conductive paths 250/250Lo/250G, typically 250, through the fully formed B2B connection interface 150.

The embodiment 1400 also shows the electrical connection and bonding (e.g., hybrid bonding) 1425 between the logic RDLs 950 and memory RDLs 1350 (RDL bonding surfaces 914/1314) to form the final RDL conductors 1450 and complete the connection paths 250 (local connection paths, typically 250Lo, and global connection paths, typically 250G) passing through the B2B connection interface 150. The bonding, e.g., hybrid bonding, also bonds together 1420 the ILD of the logic ILD 920 bottom surface 901 and the memory ILD 1320 bottom surface 1301 at the locations that are not bound by fusing conductive material (e.g., metal) 1425, i.e., where there is a logic RDL 950 logic bonding surface 914 and a memory RDL 1350 bonding surface 1314 bound together.

In some embodiments, the logic die 850 assembly 900 is moved by the logic device handler/carrier 450 and/or the memory die 1300 assembly 1305 is moved by the memory device handler/carrier 1150 until the logic ILD 920 bottom surface 901 and the memory ILD 1320 bottom surface 1301 are positioned to face and contact one another. In addition, and as a result, the logic RDL 950 bonding surface 914 the memory RDL 1350 bonding surface 1314 of the respective logic RDL 950 conductors and memory RDL 1350 conductors are made to face and contact one another.

Without loss of generality, it is noted that this positioning and contacting of the logic bonding surfaces 914 and memory bonding surfaces 1314 can be achieved by multiple methods which would be known to one skilled in the art given this disclosure. For example, the logic device handler 450 can move the logic die 850 to a stationary memory die 1300, the memory device handler 1150 can move the memory die 1300 to a stationary logic die 850, or both the logic die 850 and the memory die 1300 can be moved together by their respective handlers 450/1150. Alternatively, movable conveyors (using the handlers 450/1150 or not) can attach to the logic dies 850 and/or memory dies 1300 and move the logic 850 and/or memory 1300 dies together in the orientation described for the bonding. Other methods for positioning the logic 850 and/or memory 1300 dies are envisioned.

It is further noted that due to manufacturing tolerances, positioning errors, etc. one or more of the logic bonding surfaces 914 may not align perfectly with an associated memory bonding surface 1314. For example, there may be an offset 1410 or misalignment error 1410 that results in the entire logic bonding surface 914 and memory RDL 1350 bonding surface 1314 not being in complete contact 1410. In some embodiments, since the logic die 850 and the memory die 1300 are not of uniform shape, the larger logic RDL 950 bonding surface 914 and the memory RDL 1350 bonding surface 1314 enable enough surface area for a low resistive electrical connection even though a misalignment/offset 1410 may exist.

In some embodiments, the misalignment/offset 1410 can be between 20 nm and 300 nm and can be overcome (e.g., a good electrical contact enabled) by larger logic bonding surface areas 914 and memory bonding surface areas 1314.

Once the associated logic bonding surface 914 and memory bonding surface 1314 are positioned so they are facing one another and touching, the surfaces 914/1314 are electrically bound. Further, the logic ILD 920 bottom surfaces 901 and the memory ILD 1320 bottom surfaces 1301 are also fused (where there are no logic 914 and memory 1350 bonding surfaces).

In some embodiments, the bonding is performed by hybrid bonding, a bonding that is known to those skilled in the art. A hybrid bond is formed by bringing in to contact two flat substrates having an insulator (e.g., and ILD) and a metal surface area (e.g., the logic 914 and memory 1314 bonding surfaces are made of conductive material, like a metal such as copper) which are aligned together and annealed together through a thermal process. Thus, the ILD surfaces 920/1320 fused together and the metal portions 914/1314 electrically connected and annealed together.

After the hybrid bonding, a permanent bond and electrical connection 1425 is made between the associated logic RDL 950 bonding surfaces 914 and the memory RDL 1350 bonding surfaces 1314 to make the RDLs 1450. In some embodiments, the formation of the RDLs complete the connection paths 250, including the local connection paths 250Lo and the global connection paths 250G. The connection paths 250 make the respective electrical connections between the logic backside interconnects (e.g., a logic local via, typically 188, a logic device interconnection, typically 122, or a logic global via 134, etc.) and the memory backside interconnects (e.g., a memory local via, typically 198, a memory device interconnection, typically 142, or a memory global via 164, etc.).

The hybrid bond 1425/1420 joins the logic die 850 and memory die 1300 builds together. In some embodiments, the term “hybrid” refers to the presence of both metal 1425 and dielectric 1420 bonds. A bond that uses dielectric alone 1420 is referred to as fusion bonding (e.g., ILD to ILD). The metal to metal (e.g., copper) connections 1425 occur at the joining of the associated logic RDL 950 bonding surfaces 914 and the memory RDL 1350 bonding surfaces 1314.

The logic die 850 and memory die 1300 builds are brought together and a small heat treatment/annealing process is carried out. The ILD surfaces 914/1314 bond/fuse together and the metals surfaces 914/1314 “anneal,” or almost melt, together, thus fusing the interface 1425/1420 into a single bonded part (in some instances, seamlessly, i.e., the interface line 1425/1420 disappears). Bonding the metal surfaces 914/1314 connects the logic connection paths 250L and memory connection paths 250M, respectively, to make the final connection paths 250. In some embodiments, the annealing temperature is equal to 400 degrees Celsius or less. Various hybrid bonding techniques are known and are contemplated.

In some embodiments, once the hybrid bonding is completed, the handlers 450 and 1150 are removed as described above or by other methods known to those skilled in the art.

Using techniques and process steps known to those skilled in the art, the memory device/chip 100 is completed by making contact from logic external contacts 127 and/or memory external contacts 147 to device substrate connections 108 and/or attaching the chip/device to the device substrate 105 as shown and described above. See FIG. 1.

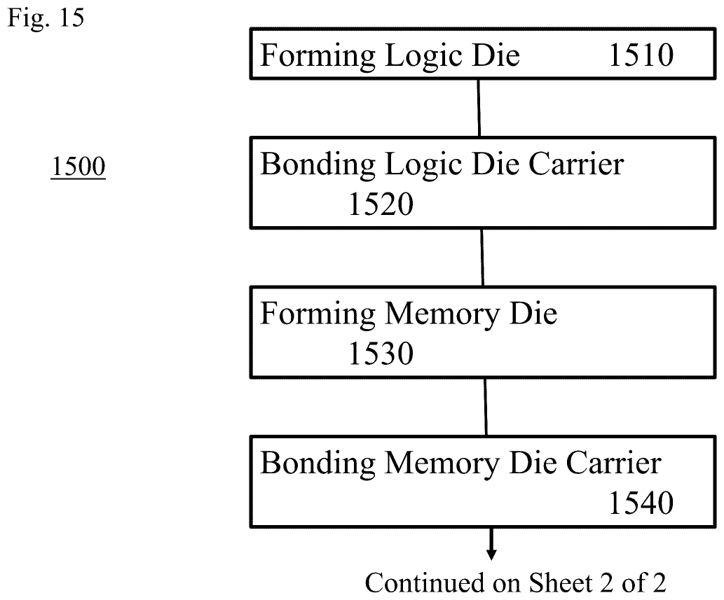

FIG. 15 is sheet 1 of 2 sheets of a flow chart of a process 1500 for making a memory chip 100, e.g., a SRAM 100, that is a combination of a logic die 850 and memory die 1300 where the logic and memory connections are connected by/within connection paths 250 (as a non-limiting example, 250L and 250M) through a B2B connection interface 150.

The process begins with forming the logic die 850 in step 1510 by performing the processes disclosed in the description of FIGS. 3-9. This process step 1510 includes the steps until the logic interface 925 is completed.

In step 1520, the logic die carrier 450 is bound, e.g., with an adhesive, to the logic die 850 as disclosed in the discussion of FIG. 4. As described above, in alternative embodiments, the logic die 850 can be bound and moved by other structures, for example, wafters or conveyer belt like carriers. Any methods known in the prior art for moving and/or positioning semiconductor structures are envisioned. As explained, the carrier 450 can be attached and/or removed at various times in the construction of the logic die 850 and/or final memory device/chip 100/1400.

In step 1530, the memory die 1300 is formed as described in the description of FIGS. 10-13 This process step 1530 includes the steps until the memory interface 1325 is completed. The memory die carrier can be bound to the memory die 1300 at step 1540 at various times in the process, depending on the embodiment, as explained above.

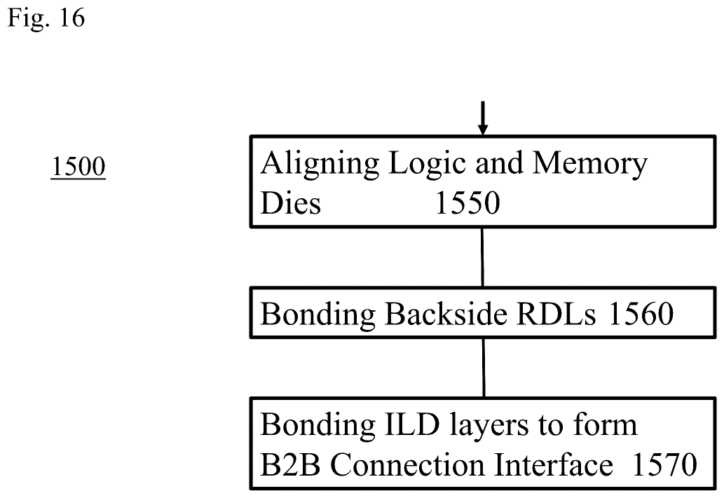

FIG. 16 is sheet 2 of 2 sheets of a flow chart of the continuation of process 1500 for making a memory chip/device 100, e.g., a SRAM 100, that is a combination of a logic die and memory die where the logic and memory are connected B2B by connection paths 250 through a B2B connection interface 150.

In step 1550 the logic die 850 and/or the memory die 1300 are moved and positioned to align and contact one another so that associated logic bonding surfaces 914 and memory bonding surfaces 1314 are positioned to face and touch one another. The surfaces 914/1314 are electrically bound, e.g., by hybrid bonding, to form the backside RDLs 1450 in step 1560. In step 1570, the logic ILD 920 bottom surfaces 901 and the memory ILD 1320 bottom surfaces 1301 (where there are no logic 914 and memory 1350 bonding surfaces) are also fused together.

Forming the RDLs 1450 and fusing together the logic ILD 920 and memory ILD 1320 bottom surfaces 1301 completes the formation of the backside to backside (B2B) connection interface (B2B interface) 150 and makes the connections to form the back-to-back connection paths 250 (including the local connection paths 250Lo and the global connection paths 250G).

The description of the various embodiments has been presented for purposes of illustration and description but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A memory device comprising:
a logic die comprising:
a logic dielectric layer, the logic dielectric layer having a plurality of logic openings and a logic dielectric layer thickness;
a logic device layer disposed on the logic dielectric layer, the logic device layer having a logic device layer thickness;
a plurality of logic devices being within the logic device layer, each of the logic devices having one or more logic device connections;
a memory die comprising:
a memory dielectric layer, the memory dielectric layer having a plurality of memory openings, and a memory dielectric layer thickness;
a memory device layer disposed on the memory dielectric layer, the memory device layer having a memory device layer thickness;
a plurality of memory devices being withing the memory device layer, one or more of the memory devices having one or more memory device connections, and
a backside to backside connection interface (B2B interface), the B2B interface having an interface memory side and an interface logic side, the interface memory side and interface logic side being opposite from one another across the B2B interface, the B2B having an interface thickness, the B2B interface being disposed between the logic dielectric layer and the memory dielectric layer, the memory dielectric layer disposed on the interface memory side and the logic dielectric layer being disposed on the interface logic side.

2. The memory device, as in claim 1, further comprising a plurality of connection paths, each of the connection paths electrically connecting one or more of the logic device connections to one or more of the memory device connections, the connection paths passing through the B2B interface.

3. The memory device, as in claim 2, further comprising one or more of the connection paths that connects a logic global via to a memory global via and pass through the B2B interface.

4. The memory device, as in claim 2, where one or more of the connection paths further comprises one or more backside logic contacts in the logic die, the backside logic contacts having a logic tapered shape, the logic tapered shape having a logic larger cross-section and a logic smaller cross-section, the logic smaller cross-section in direct contact with one of the logic openings and one or more of the logic device connections and the logic larger cross-section being contained within the B2B interface.

5. The memory device, as in claim 4, where one or more of the connection paths further comprises a logic dielectric cap in electrical series with one of the backside logic contacts.

6. The memory device, as in claim 5, where the logic dielectric cap is made from one of the following dielectric materials: SiN, SiOCN, SiBCN, SiCO, SiC, SiCN, AlOx, and AlNx.

7. The memory device, as in claim 2, where one or more of the connection paths further comprises one or more backside memory contacts in the memory die, the backside memory contacts having a memory tapered shape, the memory tapered shape having a memory larger cross-section and a memory smaller cross-section, the memory smaller cross-section in contact with one of the memory dielectric layer openings and one or more of the memory device connections, and the memory larger cross-section being contained within the B2B interface.

8. The memory device, as in claim 7, where one or more of the connection paths comprises a memory dielectric cap in electrical series with one of the backside memory contacts.

9. The memory device, as in claim 2, where one or more of the connection paths has a connection path length and the connection path length is less than or equal to the sum of the following: the logic dielectric layer thickness, the logic device layer thickness, the interface thickness, the memory dielectric layer thickness, and the memory device layer thickness.

10. The memory device, as in claim 9, where the connection path lengths are less than 1200 nanometers (nm).

11. A static random access memory (SRAM) device comprising:
a logic die comprising:
a logic dielectric layer, the logic dielectric layer having a plurality of logic openings, and a logic dielectric layer thickness;
a logic device layer disposed on the logic dielectric layer and having a logic device layer thickness,
a plurality of logic devices being within the logic device layer, each of the logic devices having one or more logic device connections;
an SRAM memory die comprising:
a memory dielectric layer, the memory dielectric layer having a plurality of memory dielectric layer openings and a memory dielectric layer thickness;
a memory device layer disposed on the memory dielectric layer, the memory device layer having a memory device layer thickness;
a plurality of SRAM memory devices being within the memory device layer, one or more of the SRAM memory devices having one or more memory device connections, and
a backside to backside (B2B) connection interface (B2B interface), the B2B interface having an interface memory side and an interface logic side, the interface memory side and interface logic side being opposite from one another across the B2B interface, the B2B having an interface thickness, the B2B interface further comprising a memory interlayer dielectric (ILD) on the interface memory side and a logic ILD on the interface logic side, the memory ILD further comprising:
one or more memory backside contacts, the memory backside contacts having a non-uniform shape with a memory backside contact smaller cross-section part and a memory backside contact larger cross-section part, each of the memory backside contact smaller cross-section parts in contact with one of the memory dielectric layer openings and being in contact with one or more of the memory device connections;
one or more memory redistribution layers (memory RDLs) within the memory ILD, each memory RDL having a memory RDL backside contact side and a memory RDL bonding surface, the memory RDL bonding surface being across the memory RDL from the memory RDL backside contact side, the memory RDL backside contact side being in electrical contact with the larger cross-section part of one or more of the memory backside contacts, where a partial memory connection path is formed by the electrical connection of one or more of the memory device connections, one of the memory backside contacts and one of the memory RDLs, and
the logic ILD further comprising:
one or more logic backside contacts, the logic backside contacts having a non-uniform shape with a logic backside contact smaller cross-section part and a logic backside contact larger cross-section part, each of the logic backside contact smaller cross-section parts in direct contact with one of the logic openings and being in contact with one or more of the logic device connections;
one or more logic redistribution layer (logic RDLs) within the logic ILD, each logic RDL having a logic RDL backside contact side and a logic RDL bonding surface, the logic RDL bonding surface being across the logic RDL from the logic RDL backside contact side, the logic RDL backside contact side being in electrical contact with the larger cross-section part of one or more of the logic backside contacts, where a partial logic connection path is formed by the electrical connection of one or more of the logic device connections, one of the logic backside contacts, and one of the logic RDLs,
where the memory RDL bonding surface of one of the memory RDLs and the logic RDL bonding surface of one of the logic RDLs are electrically connected and bonded together to electrically connect the partial memory connection path and the partial logic connection path forming a connection path through the B2B interface that connects one or more of the logic device connections to one or more of the memory device connections, the connection path having a connection path length that is less than 1200 nanometers long.

12. The SRAM device, as in claim 11, where one of the logic backside contact smaller cross-section parts connects to a logic global via passing through the logic die and one of the memory backside contact smaller cross-section parts connects to a memory global via passing through the memory die so that the connection path through the B2B interface electrically connects the logic global via to the memory global via.

13. The SRAM device, as in claim 11, where one of the logic backside contact smaller cross-section parts passes through one of the logic openings and one of the memory backside contact smaller cross-section parts passes through one of the memory dielectric layer openings.

14. The SRAM device, as in claim 11, where a logic dielectric cap is in series electrically in one of the partial logic connection paths.

15. The SRAM device, as in claim 14, where the logic dielectric is placed between the larger cross-section part of the logic backside contact and the logic RDL backside contact side and further where the logic dielectric is made of a dielectric material.

16. The SRAM device, as in claim 11, where a memory dielectric cap is in series electrically in one of the partial memory connection paths.

17. The SRAM device, as in claim 16, where the memory dielectric is placed between the larger cross-section part of the memory backside contact and the memory RDL backside contact side and further where the memory dielectric is made of a dielectric material.

18. The SRAM device, as in claim 11, where the logic RDL backside contact side of one or more of the logic RDLs is connected to the larger cross-section part of at least two logic backside contacts and where at least one of the logic backside contacts is connected through a dielectric cap to the logic RDL backside contact side and at least one of the logic backside contacts is in direct contact with logic RDL backside contact side.

19. The SRAM device, as in claim 11, where there is an offset between the logic bonding surface and memory RDL bonding surface.

20. A method of making a memory device comprising the steps of:
forming a logic die by performing the steps of:
disposing a logic dielectric layer on an interim logic substrate, the logic dielectric layer having a plurality of logic openings, and a logic dielectric layer thickness;
growing a logic device layer on the logic dielectric layer, the logic device layer having a logic device layer thickness;
growing a plurality of logic devices on the logic device layer, each of the logic devices having one or more logic device connections;
forming a memory die by performing the steps of:
disposing a memory dielectric layer on an interim memory substrate, the memory dielectric layer having a plurality of memory dielectric layer openings, and a memory dielectric layer thickness;
growing a memory device layer on the memory dielectric layer, the memory device layer having a memory device layer thickness;
growing a plurality of memory devices on the memory device layer, one or more of the memory devices having one or more memory device connections;
bonding a logic carrier to the logic die, bonding a memory carrier to the memory, removing the interim logic substrate from the logic die, and removing the interim memory substrate from the memory die;
depositing a logic interlayer dielectric (logic ILD) on the logic dielectric layer, the logic ILD containing one or more logic backside contacts and one or more logic redistribution layer (logic RDLs) within the logic ILD, the logic backside contacts connecting one or more of the logic device connections to one more of the logic RDLs;
depositing a memory interlayer dielectric (memory ILD) on the memory dielectric layer, the memory ILD containing one or more memory backside contacts and one or more memory redistribution layer (memory RDLs) within the memory ILD, the memory backside contacts connecting one or more of the memory device connections to one more of the memory RDLs;
moving the logic die and memory die together so that the logic RDLs contact the memory RDLs; and
forming a backside to backside (B2B) connection interface (B2B interface) by hybrid bonding together the logic RDLs and memory RDLs to form a connection path through the B2B interface that connects one or more of the logic device connections to one or more of the memory device connections.
